(19) United States
(12) Patent Application Publication
(10) Pub. No.: US 2025/0218775 A1
(43) Pub. Date: Jul. 3, 2025

(54) MATERIALS AND METHODS FOR FORMING PATTERNED MASK ON SUBSTRATE

(71) Applicant: Tokyo Electron Limited, Tokyo (JP)

(72) Inventors: Phillip D. Hustad, Longmont, CO (US); Jordan B. Greenough, Schenectady, NY (US); Max J. Klemes, Schenectady, NY (US)

(21) Appl. No.: 18/988,437

(22) Filed: Dec. 19, 2024

Related U.S. Application Data
(60) Provisional application No. 63/616,068, filed on Dec. 29, 2023.

(51) Int. Cl. H01L 21/033; G03F 7/00; G03F 7/09; G03F 7/16

(52) U.S. Cl. CPC H01L 21/0337; G03F 7/0035; G03F 7/094; G03F 7/168

(57) ABSTRACT

A method includes forming mandrels over a substrate. The mandrels include a first material having a first solubility-shifting mechanism. The method further includes absorbing a solubility-shifting agent into the mandrels to form absorbed regions in the mandrels and depositing a resist layer over the mandrels and the substrate. The resist layer includes a second material having a second solubility-shifting mechanism different from the first solubility-shifting mechanism. The method further includes diffusing a catalyst of/from the solubility-shifting agent into the resist layer to form solubility-shifted regions in the resist layer, and selectively removing the solubility-shifted regions of the resist layer. Remaining regions of the resist layer and the mandrels form a patterned mask over the substrate.

### CROSS-REFERENCE TO RELATED APPLICATIONS

This application claims the benefit of U.S. Provisional Application No. 63/616,068, filed on Dec. 29, 2023, which application is hereby incorporated herein by reference.

### TECHNICAL FIELD

The present disclosure relates generally to methods for processing a substrate, and, in particular embodiments, to photolithography materials and processes in methods for forming a patterned mask on a substrate during manufacturing of semiconductor devices.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning of nanoscale features.

### SUMMARY

In accordance with an embodiment of the present disclosure, a method includes forming mandrels over a substrate. The mandrels include a first material having a first solubility-shifting mechanism. The method further includes absorbing a solubility-shifting agent into the mandrels to form absorbed regions in the mandrels and depositing a resist layer over the mandrels and the substrate. The resist layer includes a second material having a second solubility-shifting mechanism different from the first solubility-shifting mechanism. The method further includes diffusing a catalyst of/from the solubility-shifting agent into the resist layer to form solubility-shifted regions in the resist layer, and selectively removing the solubility-shifted regions of the resist layer. Remaining regions of the resist layer and the mandrels form a patterned mask over the substrate.

In accordance with another embodiment of the present disclosure, a method includes forming a first patterned resist layer over a substrate. The first patterned resist layer includes a first material including acid-labile groups. The method further includes absorbing a solubility-shifting agent into the first patterned resist layer to form absorbed regions in the first patterned resist layer and depositing a second resist layer over the first patterned resist layer and the substrate. The second resist layer includes a second material including curable groups and cleavable groups. The method further includes generating a catalyst from the solubility-shifting agent, diffusing the catalyst into the second resist layer to form deprotected regions in the second resist layer, and selectively removing the deprotected regions of the second resist layer. Remaining regions of the second resist layer and the first patterned resist layer form a patterned mask over the substrate.

In accordance with yet another embodiment of the present disclosure, a method includes forming a first patterned resist layer over a substrate. The first patterned resist layer includes a first material comprising acid-labile groups. The method further includes depositing an overcoat over the first patterned resist layer and the substrate. The overcoat includes a solubility-shifting agent. The method further includes absorbing the solubility-shifting agent into the first patterned resist layer to form absorbed regions in the first patterned resist layer, selectively removing the overcoat, and depositing a second resist layer over the first patterned resist layer and the substrate. The second resist layer includes a degradable thermoset. The method further includes generating a catalyst from the solubility-shifting agent, diffusing the catalyst into the second resist layer to form deprotected regions in the second resist layer, and selectively removing the deprotected regions of the second resist layer. Remaining regions of the second resist layer and the first patterned resist layer form a patterned mask over the substrate.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1H illustrate cross-sectional views of intermediate stages in the manufacturing of a patterned mask over a substrate in accordance with various embodiments; and

FIG. 2 illustrates a flow diagram of a method for forming a patterned mask over a substrate in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

The disclosure relates to methods for forming patterned masks on substrates using solubility shifting agents (SSAs). In various embodiments, mandrels comprising a first material with acid-labile groups are formed over a substrate, and an SSA is absorbed into the mandrels to form absorbed regions. A resist layer comprising a second material with a different solubility-shifting mechanism, such as a degradable thermoset with curable and cleavable groups, is deposited over the mandrels and substrate. The SSA generates a catalyst that diffuses from the absorbed regions into perimeter portions of the resist layer to form anti-spacer regions through chemical transformation.

The chemically transformed anti-spacer regions become selectively removable using a suitable developer, while untransformed portions remain insoluble. When the anti-spacer regions are removed, the remaining portions of the resist layer and mandrels form a patterned mask with openings corresponding to where the anti-spacer regions were located. The width of these openings can be controlled by tuning process parameters that affect the diffusion depth of the catalyst and chemical transformation. The pattern can then be transferred to the underlying substrate through subsequent processing steps.

Various embodiments of the present disclosure offer several advantages. Various embodiments provide improved control over pattern dimensions and spacing by utilizing controlled diffusion of catalysts from absorbed regions to form anti-spacer regions. The two-resist layer approach using materials with different solubility-shifting mechanisms allows for selective removal of transformed regions while maintaining the structural integrity of untransformed areas. This enables the formation of well-defined openings with tunable widths based on diffusion depth, which can be adjusted through process parameters like temperature, time, and material selection.

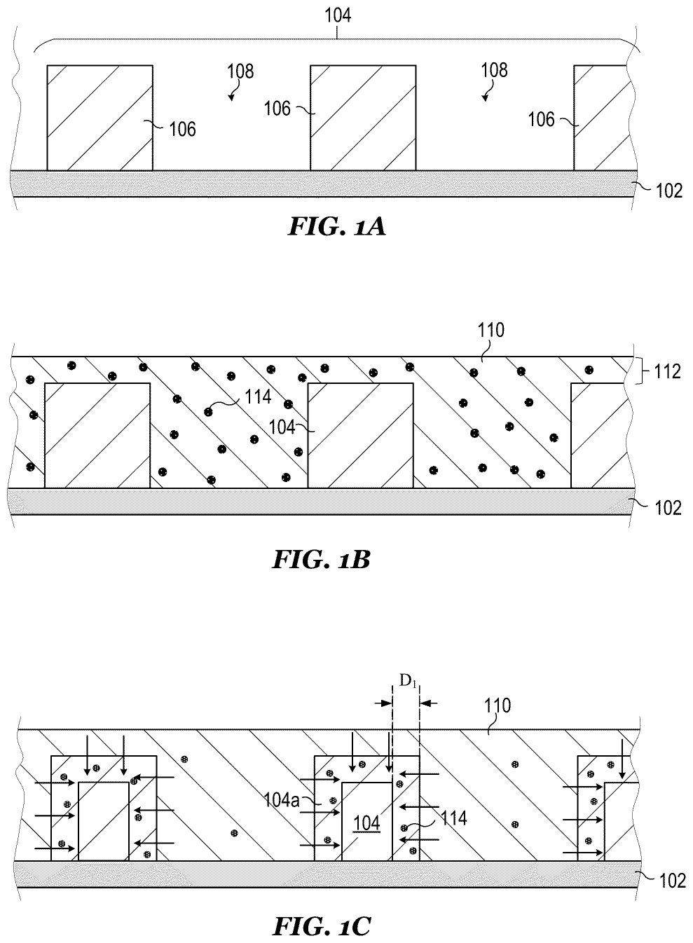

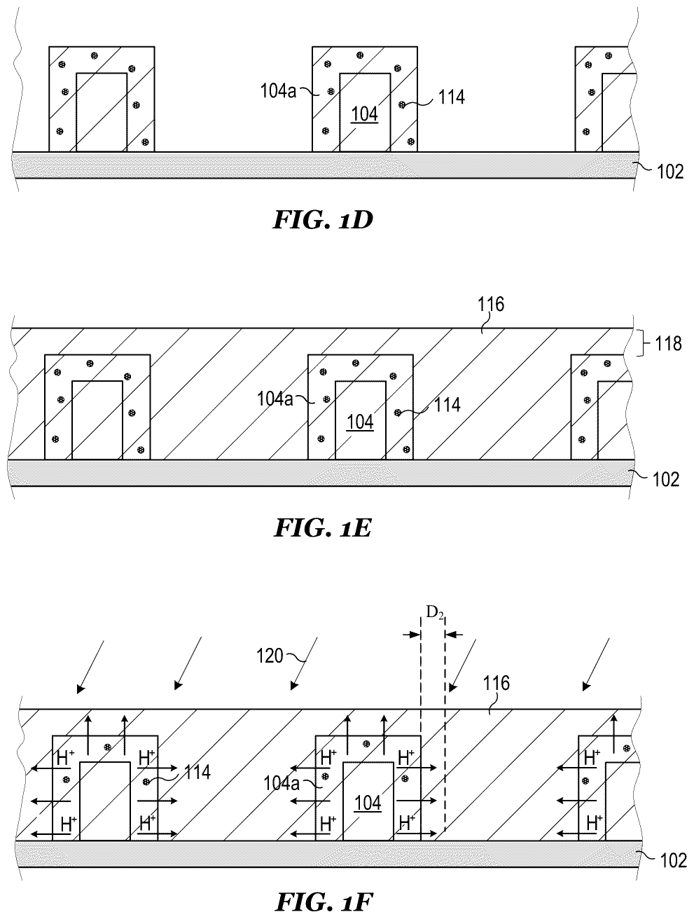

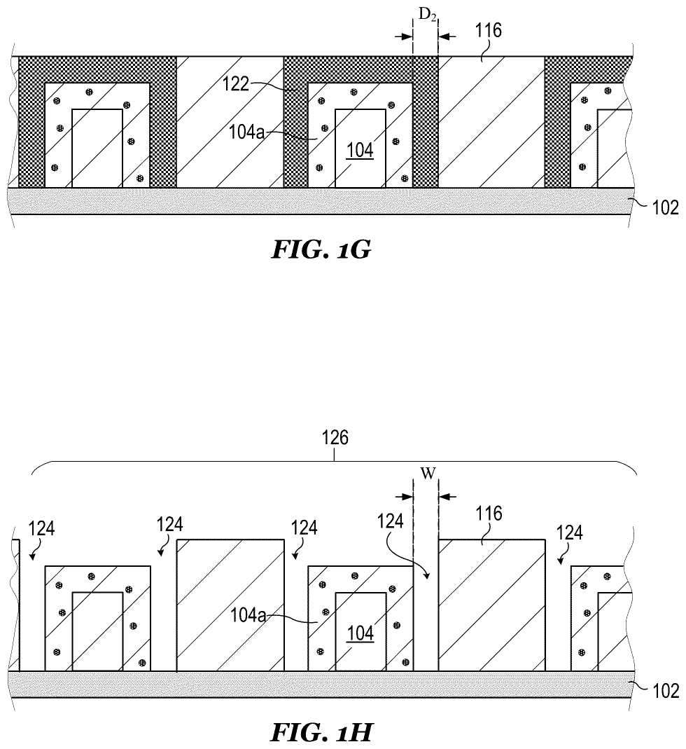

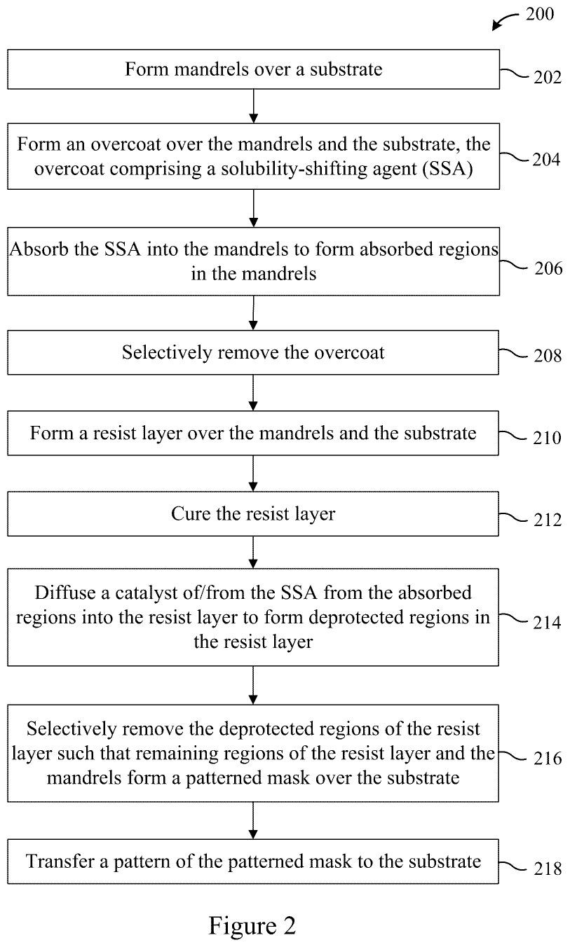

Some example embodiments of the present disclosure are described in detail with reference to FIGS. 1A-1H and 2.

FIGS. 1A-1H illustrate cross-sectional views of intermediate stages in the manufacturing of a patterned mask over a substrate in accordance with various embodiments. Referring to FIG. 1A, a first patterned resist layer 104 can be provided on a substrate 102. The first patterned resist layer 104 can have a pattern of mandrels 106 and openings 108 formed therein and extending to the substrate 102, for example, to form a relief pattern. The first patterned resist layer 104 can include a solubility shifting agent (SSA) therein. The first patterned resist layer 104 can be formed using any suitable process, which will not be described in detail herein because there can be many different processes that can be used to create the first patterned resist layer 104 as can be apparent to one of ordinary skill in the art when implementing an embodiment of the present disclosure.

The first patterned resist layer 104 can include a first material, and the first material can include the SSA therein. In some embodiments, the SSA can be formed in situ during the deposition of the first material, during the formation of first patterned resist layer 104. In such embodiments, the SSA can be evenly distributed throughout the first material, for example, but not necessarily. In some embodiments, the first patterned resist layer 104 of the first material can be deposited without the SSA and the SSA can be put into the first material of the first patterned resist layer 104 thereafter. For example, in some embodiments, the SSA can be implanted or diffused into the first material of the first patterned resist layer 104. The first material of the first patterned resist layer 104 can be soluble in a first developer containing an organic solvent and insoluble in a second developer containing a quaternary ammonium hydroxide in an aqueous solution (e.g., TMAH), or a combination thereof.

In the present disclosure, for an embodiment, the term “substrate” (e.g., substrate 102) can be used generally and as a shorthand description for an underlying structure that can include any combination of layers, materials, structures, devices, and a wafer of any suitable structure. For example, the substrate 102 of an embodiment can include one or more bottom anti-reflective coating (BARC) layers, one or more developable BARC (dBARC) layers, one or more etch stop layers, one or more hard mask layers, one or more dielectric layers, one or more intermetal dielectric layers, one or more conductive lines/layers/interconnects, one or more transistor structures, one or more capacitor structures, one or more resistor structures, one or more inductor structures, one or more memory cells, or any combination thereof.

In some embodiments, the SSA may include an agent-generating ingredient that, in response to a suitable agent-activation trigger (e.g., heat and/or radiation), generates a solubility-changing chemical or a catalyst (e.g., an acid). Example agent-generating ingredients can include a thermal-acid generator (TAG) that is configured to generate an acid in response to heat or a photo-acid generator (PAG) that is configured to generate an acid in response to actinic radiation.

While describing the example embodiments of the present disclosure, the term “solubility shifting agent” or “SSA” can refer to a substance in a general sense that if not already a catalyst agent itself, it can generate and/or can transform (e.g., by heat and/or certain radiation of light) to a catalyst agent and/or constituent parts that includes a catalyst agent that can be used in a chemical reaction to shift or change a solubility property of a material.

In some embodiments when the SSA comprises a PAG, after forming the first material of the first patterned resist layer 104, a reticle (not shown) may be disposed over the first material. The reticle may be used to modulate a dose (or an intensity) of a radiation (e.g., actinic radiation) that is used to expose the first material. In such embodiments, the reticle may comprise regions of different transparency to the radiation (e.g., opaque and transparent regions). The first material is then subject to an exposure step through the reticle. The radiation exposes exposed regions of the first material while unexposed (or unmodified) regions of the photoresist layer are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology.

In some embodiments, the radiation generates a catalyst (e.g., an acid) in the exposed regions of the first material. The catalyst can be generated from the SSA (e.g., PAG) that is present in the first material under the influence of the radiation and chemically transforms exposed portions of the first material to converted region of a second material using the catalyst as a chemical reaction catalyst, such that the second material is soluble in a suitable developer. In an embodiment, the suitable developer comprises a quaternary ammonium hydroxide in an aqueous solution (e.g., TMAH). Subsequently, the exposed regions of the first material may be removed by performing a developing process using a positive-tone developer (e.g., TMAH). The developing process forms the openings 108 in the first material that expose portions of the substrate 102. The unexposed regions of the first material form the plurality of mandrels 106. In other embodiments, the unexposed regions of the first material may be removed by performing a developing process using a negative-tone developer (e.g., organic developer). In such embodiments, the exposed regions of the first material form the plurality of mandrels. In an embodiment, the organic developer may comprise n-butyl acetate (NBA), 2-heptanone, a combination thereof, or the like.

In the present disclosure, the terms “soluble” and “insoluble” are used in a relative sense, not in an absolute sense. That is, the term “insoluble” as used herein refers to one subject material being dissolved or removed much faster and much more effectively compared to another adjacent non-subject material, such as an order of magnitude or more faster and more effectively, and not to necessarily be that the other adjacent non-subject material experiences no dissolving or removal, but rather that the subject material is removed so much faster and more effectively that the subject material can be dissolved and removed sufficiently or to its full extent while only a small amount or even only a negligible amount of the other adjacent non-subject material is dissolved and removed, such that most of or almost all of the other adjacent non-subject material at the stopping point of the dissolving and removing of the subject material, as can be apparent to one of ordinary skill in the art pertaining to the present disclosure.

Referring to FIG. 1B, an overcoat 110 can be deposited over the first patterned resist layer 104 and the substrate 102. In some embodiments, a relief pattern of the first patterned resist layer 104 is stabilized prior to depositing the overcoat 110. Various resist stabilization techniques, also known as freeze processes, have been proposed such as ion implantation, UV curing, thermal hardening, thermal curing and chemical curing. The overcoat 110 can include a third material, and the third material can include an SSA 114 therein. In some embodiments, the SSA 114 may be formed using similar materials and methods as the SSA of the first patterned resist layer 104 described above with reference to FIG. 1A, and the description is not repeated herein. In some embodiments, the third material may be selected such that it is soluble in a suitable solvent that does not dissolve the patterned first resist layer 104. In an embodiment, the suitable solvent may comprise an organic solvent.

The overcoat 110 can be deposited using any suitable process, such as spin-on coating/deposition, for example. The overcoat 110 can have an overburden 112 deposited higher than a highest feature of the first patterned resist layer 104, which can be a normal occurrence when using a spin-on coating process for deposition, for example. In some embodiments, there may be no overburden 112 or very minimal (insubstantial) thickness of overburden 112. The process for depositing the overcoat 110 will not be described in detail here because there can be many different processes that can be used to create the overcoat 110, as can be apparent to one of ordinary skill in the art when implementing an embodiment of the present disclosure.

In other embodiments, the overcoat 110 can be deposited as a conformal layer over the first patterned resist layer 104 and the substrate 102. In such embodiments, the overcoat 110 may not fill the openings 108 (see FIG. 1A).

Referring to FIG. 1C, the SSA 114 from the overcoat 110 can be absorbed into outer regions of the first patterned resist layer 104 to a first depth D₁ to form absorbed regions 104a in the first patterned resist layer 104. In some embodiments, the absorption process comprises performing a baking process that diffuses the SSA 114 from the overcoat 110 into the first patterned resist layer 104. In an embodiment, the baking process can be a thermal process that is performed by heating the wafer in a process chamber to a temperature between 50° C. and 150° C., in vacuum or under a gas flow. In a particular example, the wafer can be baked for a duration in a range from 0.5 to 5 minutes.

In an embodiment when the SSA 114 comprises a free acid, a composition and concentration of the free acid is such that the free acid does not alter solubility of the absorbed regions 104a. In an embodiment when the SSA 114 comprises a TAG, parameters (e.g., temperature) of the baking process may be tuned such that a catalyst (e.g., acid) is not generated from the SSA 114. For example, a temperature of the baking process may be tuned to be less than an activation temperature of the SSA 114.

Referring to FIG. 1D, the overcoat 110 (see FIG. 1C) can be selectively removed using a suitable solvent leaving behind the first patterned resist layer 104 (including the absorbed regions 104a). In some embodiments, the suitable solvent may be chosen such that the overcoat 110 is soluble in the suitable solvent while the first patterned resist layer 104 (including the absorbed regions 104a) are insoluble in the suitable solvent. In an embodiment, the suitable solvent may comprise an organic solvent.

Referring to FIG. 1E, a second resist layer 116 can be deposited over the first patterned resist layer 104 (including the absorbed regions 104a) and the substrate 102. In some embodiments, a material for the second resist layer 116 is chosen such that the second resist layer 116 has a different solubility-shifting mechanism compared to the first patterned resist layer 104. In some embodiments, the second resist layer 116 may comprise a material that is soluble in organic solvents to enable film coating, crosslinks or cures or otherwise becomes insoluble to the organic solvent after coating, and de-crosslinks or otherwise becomes soluble again when treated with a catalyst portion of/from an SSA. In some embodiments, the material of the second resist layer 116 may comprise a curable group and a cleavable group. In an embodiment, the material of the second resist layer 116 may comprise a degradable thermoset. In embodiments when the second resist layer 116 comprises a polymer, the polymer can be a polymer made from monomers including acrylates, methacrylates, norbornene, vinyl aromatic monomers such as styrene and p-hydroxystyrene, combinations thereof, or the like. In some embodiments, the degradable thermosets include polyacrylate phthalates, polystyrene phthalates, polystyrene alcohols, polymethacrylate alcohols, polyacrylate alcohols, polymethacrylate acrylates, polyacrylate acrylates, combinations thereof, and the like.

The second resist layer 116 can be deposited using any suitable process, such as spin-on coating/deposition, for example. The second resist layer 116 can have an overburden 118 deposited higher than a highest feature of the first patterned resist layer 104 (including the absorbed regions 104a), which can be a normal occurrence when using a spin-on coating process for deposition, for example. In some embodiments, there may be no overburden 118 or very minimal (insubstantial) thickness of overburden 118. The process for depositing the second resist layer 116 will not be described in detail here because there can be many different processes that can be used to create the second resist layer 116, as can be apparent to one of ordinary skill in the art when implementing an embodiment of the present disclosure.

In some embodiments, after depositing the material of the second resist layer 116, a curing process is performed on the material of the second resist layer 116 to cross-link monomers of the material. The cross-linking alters solubility of the second resist layer 116 such that the second resist layer 116 becomes insoluble in organic solvents. In an embodiment, the curing process can be a thermal process that is performed by heating the wafer in a process chamber to a temperature between 50° C. and 150° C., in vacuum or under a gas flow. In a particular example, the wafer can be baked for a duration in a range from 0.5 to 5 minutes.

Referring to FIGS. 1F and 1G, at least a catalyst portion (represented as “H⁺” in FIG. 1F) of/from the SSA 114 can be diffused from the absorbed regions 104a into perimeter regions of the second resist layer 116 to a second depth D₂. The perimeter regions of the second resist layer 116 can be adjacent the absorbed regions 104a and can be regions immediately adjacent and having physical contact with the absorbed regions 104a.

The perimeter regions of the second resist layer 116 can be chemically transformed into anti-spacer regions 122 of a converted material using the free acid (represented as H⁺ in FIG. 1F) as a chemical reaction catalyst, such that the converted material is soluble in a suitable developer and untransformed remaining portions of the second resist layer 116 are not soluble or are orders of magnitude less soluble to the suitable developer. In an embodiment, the suitable developer may comprise an organic solvent. In some embodiments, the free acid (represented as H⁺ in FIG. 1F) cleaves cleavable bonds of cleavable groups of the material of the second resist layer 116 and alters solubility of the converted material. The anti-spacer regions 122 may be also referred to as deprotected regions or solubility-shifted regions.

In FIG. 1F, for simplification of the drawings, “H⁺” can be used as shorthand notation to denote and represent a catalyst, which in some embodiments can be an acid, that is being diffused, such as an acid that donates a proton (e.g., H⁺) in a chemical reaction (e.g., as a catalyst). However, an acid being diffused in an embodiment of the present disclosure is not necessarily limited to one that provides a hydrogen ion. For example, “H⁺” may not necessarily accurately describe some acid species that can be used in an embodiment of the present disclosure, as can be apparent to one of ordinary skill in the art for which the present disclosure pertains. Thus, the use of “H⁺” is as a reference in the drawings for the catalyst is not intended to necessarily limit the chemical makeup or chemical action of the catalyst in an embodiment.

In an embodiment when the SSA 114 is a free acid, during a baking operation, the free acid (represented as H⁺ in FIG. 1F) can diffuse from the absorbed regions 104a into perimeter regions of the second resist layer 116 to the second depth D₂ to form the anti-spacer regions 122.

In another embodiment when the SSA 114 is a TAG, baking the wafer can cause the TAG to generate a catalyst (e.g., acid, represented as H⁺ in FIG. 1F), which can be referred to as activating the acid, and the baking can also cause the generated catalyst to diffuse into perimeter portions of the second resist layer 116 to the second depth D₂ to form the anti-spacer regions 122. In some embodiments when the first patterned resist layer 104 includes a TAG, parameters (e.g., temperature) of the baking process may be tuned such that a catalyst (e.g., acid) is not generated from the TAG. For example, a temperature of the baking process may be tuned to be less than an activation temperature of the TAG.

In yet another embodiment when the SSA 114 is a PAG, the absorbed regions 104a can be exposed to a radiation (e.g., actinic radiation) that can be performed prior to baking the wafer. Such exposure to radiation can cause the PAG to generate a catalyst (e.g., acid, represented as H⁺ in FIG. 1F), which can be referred to as activating the acid. Then, baking of the wafer can cause the generated catalyst to diffuse into perimeter portions of the second resist layer 116 to the second depth D₂ to form the anti-spacer regions 122.

In an embodiment, the baking process for forming the anti-spacer regions 122 can be a thermal process that is performed by heating the wafer in a process chamber to a temperature between 50° C. and 150° C., for example, or between 60° C. and 130° C. in certain embodiments, in vacuum or under a gas flow. In a particular example, the wafer can be baked for a duration in a range from 0.5 to 5 minutes. The bake conditions can be selected to promote the diffusion of the catalyst (and possibly generation of the catalyst from the SSA 114, if applicable). The second depth D₂ can be tuned by parameters of the baking process (such as, for example, a bake temperature and a bake duration) and material parameters (such as, for example, a polymer composition of the second resist layer 116, and an acid composition and an acid concentration of an acid of/from the SSA 114).

In FIG. 1F, the energy from the heat and/or radiation used in the process of forming the anti-spacer regions 122 (see FIG. 1G) is illustrated generally by downward pointing arrows 120. However, as can be understood by one of ordinary skill in the art pertaining to such process, the direction(s) and vector(s) of the heat and/or radiation can be from any suitable direction(s)/vector(s) and from any suitable source of provided in a given tool. Hence, the downward pointing arrows 120 of FIG. 1F can be merely illustrative.

Referring to FIG. 1H, the anti-spacer regions 122 (see FIG. 1G) can be removed using a suitable developer to form a patterned mask 126 including remaining portions (i.e., portions unconverted by the catalyst) of the second resist layer 116 and the first patterned resist layer 104 (including the absorbed regions 104a), and having openings 124 to the substrate 102 corresponding to the anti-spacer regions 122. In an embodiment, the suitable developer may comprise an organic solvent.

Because the openings 124 of the patterned mask 126 can be formed by the removal of the anti-spacer regions 122 (see FIG. 1G), and because the anti-spacer regions 122 can have dimensions defined by or corresponding to the second depth D₂ (see FIG. 1G), at least part of the openings 124 can have a width W corresponding to the second depth D₂ (e.g., compare FIGS. 1G and 1H). The width W is not necessarily equal to the second depth D₂ in some embodiments, but can be derived from and dependent upon the second depth D₂. Thus, the width W of openings 124 can be adjusted, tuned, and specified based on parameters (e.g., temperature, bake time, etc.) for the process of diffusing the catalyst and/or the process of causing the chemical reaction to form the anti-spacer regions 122 (see FIG. 1G) of a converted material, as well as other factors, such as the choice of the substance for the catalyst, the choice of the resist material of the second resist layer 116, other additives/substances present in the second resist layer 116, or any suitable combination thereof, for example.

Although only similar or same openings 124 are shown in FIG. 1H for purposes of simplified illustration, it can be apparent to one of ordinary skill in the art that in an embodiment there can be numerous different openings for the patterned mask 126 of various shapes and sizes across a given die and across a wafer while implementing an embodiment of the present disclosure.

In some embodiments, a pattern defined by the patterned mask 126 can be transferred to the substrate 102. In an embodiment, the pattern transfer may be accomplished through an etching process while using the patterned mask 126 as an etch mask. In some embodiments, the etching process may be a dry etching technique such as reactive ion etching (RIE), plasma etching, or ion beam etching. In other embodiments, wet etching techniques may be employed. In some embodiments, the pattern transfer process may be followed by the removal of any remaining patterned mask 126. The removal can be accomplished using suitable solvents, plasma ashing techniques, or the like.

Many example materials for the first patterned resist layer 104, the overcoat 110 (including the SSA 114), and the second resist layer 116, relating to the example embodiments of FIGS. 1A to 1H, will be described below in the present disclosure.

FIG. 2 illustrates a flow diagram of a method 200 for forming a patterned mask over a substrate in accordance with various embodiments. In step 202, mandrels (e.g., mandrels 106) are formed over a substrate (e.g., substrate 102), as described above with reference to FIG. 1A. In step 204, an overcoat (e.g., overcoat 110) is formed over the mandrels (e.g., mandrels 106) and the substrate (e.g., substrate 102), as described above with reference to FIG. 1B. In some embodiments, the overcoat (e.g., overcoat 110) comprises a solubility-shifting agent (SSA) (e.g., SSA 114). In step 206, the SSA (e.g., SSA 114) is absorbed into the mandrels (e.g., mandrels 106) to form absorbed regions (e.g., absorbed regions 104a) in the mandrels (e.g., mandrels 106), as described above with reference to FIG. 1C. In step 208, the overcoat (e.g., overcoat 110) is selectively removed, as described above with reference to FIG. 1D. In step 210, a resist layer (e.g., resist layer 116) is formed over the mandrels (e.g., mandrels 106) and the substrate (e.g., substrate 102), as described above with reference to FIG. 1E. In step 212, the resist layer (e.g., resist layer 116) is cured, as described above with reference to FIG. 1E. In step 214, a catalyst (shown as H⁺ in FIG. 1F) of/from the SSA (e.g., SSA 114) is diffused from the absorbed regions (e.g., absorbed regions 104a) into the resist layer (e.g., resist layer 116) to form deprotected regions (e.g., anti-spacer regions 122) in the resist layer (e.g., resist layer 116), as described above with reference to FIGS. 1F and 1G. In step 216, the deprotected regions (e.g., anti-spacer regions 122) of the resist layer (e.g., resist layer 116) are selectively removed such that remaining regions of the resist layer (e.g., resist layer 116) and the mandrels (e.g., mandrels 106) form a patterned mask (e.g., patterned mask 126) over the substrate (e.g., substrate 102), as described above with reference to FIG. 1H. In step 218, a pattern of the patterned mask (e.g., patterned mask 126) is transferred to the substrate (e.g., substrate 102), as described above with reference to FIG. 1H.

For describing some example materials that can be implemented and used in an embodiment of the present disclosure, some example definitions will be provided next. These definitions are intended to supplement and illustrate, not preclude, definitions known to those of skill in the art, as can be apparent to one of ordinary skill in the art to which the present disclosure pertains.

The term “independently selected” as used herein can indicate that the R groups, such as, R1, R2, R3, R4, and R5 can be identical or different (e.g., R1, R2, R3, R4, and R5 may all be substituted alkyls or R1 and R2 may be a substituted alkyl and R3 may be an aryl, etc.). Use of the singular can include use of the plural, and vice versa (e.g., a hexane solvent can include hexanes). A named R group can generally have the structure that is recognized in the art as corresponding to R groups having that name.

The term “aliphatic” can refer to a non-aromatic saturated or unsaturated straight or branched hydrocarbon radical of from 1 to 40 carbon atoms or from 1 to 18 carbon atoms.

By “substituted” as in “substituted aliphatic moiety,” “substituted aryl,” “substituted alkyl,” and “substituted alkenyl,” as alluded to in some of the aforementioned definitions, can be indicate that in the hydrocarbyl, hydrocarbylene, alkyl, alkenyl, aryl or other moiety, at least one hydrogen atom bound to a carbon atom is replaced with one or more substituents that are groups such as hydroxyl, alkoxy, alkylthio, amino, halo, and silyl, to name a few. When the term “substituted” appears prior to a list of possible substituted groups, it can be intended that the term applies to every member of that group. For example, the phrase “substituted alkyl, alkenyl, and alkynyl” can be interpreted as “substituted alkyl, substituted alkenyl, and substituted alkynyl.” Similarly, “optionally substituted alkyl, alkenyl, and alkynyl” can be interpreted as “optionally substituted alkyl, optionally substituted alkenyl, and optionally substituted alkynyl.”

The term “substitution” can indicate each hydrogen atom (H) bonded to a carbon atom or heteroatom of a corresponding unsubstituted compound or functional group is replaced by a substituent (e.g., Rs). The term “polysubstitution” can indicate each of at least two, but not all, hydrogen atoms bonded to carbon atoms or heteroatoms of a corresponding unsubstituted compound or functional group is replaced by a substituent. The (C1-C18)alkylene and (C1-C8)alkylene substituents can be especially useful for forming substituted chemical groups that are bicyclic or tricyclic analogs of corresponding monocyclic or bicyclic unsubstituted chemical groups, for example.

The term “(C1-C40) hydrocarbyl” can refer to a hydrocarbon radical of from 1 to 40 carbon atoms and the term “(C1-C40) hydrocarbylene” can refer to a hydrocarbon diradical of from 1 to 40 carbon atoms, in which each hydrocarbon radical and diradical independently is aromatic (6 carbon atoms or more) or non-aromatic, saturated or unsaturated, straight chain or branched chain, cyclic (including mono- and poly-cyclic, fused and non-fused polycyclic, including bicyclic; 3 carbon atoms or more) or acyclic, or a combination of two or more thereof, and each hydrocarbon radical and diradical independently can be the same as or different from another hydrocarbon radical and diradical, respectively, and independently can be unsubstituted or substituted by one or more Rs.

In the present disclosure, a (C1-C40) hydrocarbyl independently can be an unsubstituted or substituted (C1-C40)alkyl, (C3-C40) cycloalkyl, (C3-C20) cycloalkyl-(C1-C20)alkylene, (C6-C40) aryl, or (C6-C20) aryl-(C1-C20)alkylene. In some embodiments, each of the aforementioned (C1-C40) hydrocarbyl groups independently has a maximum of 20 carbon atoms (i.e., (C1-C20) hydrocarbyl) and in other embodiments, a maximum of 12 carbon atoms, for example.

The terms “(C1-C40)alkyl” and “(C1-C18)alkyl” can refer to a saturated straight or branched hydrocarbon radical of from 1 to 40 carbon atoms or from 1 to 18 carbon atoms, respectively, that is unsubstituted or substituted by one or more Rs. Examples of unsubstituted (C1-C40)alkyl are: unsubstituted (C1-C20)alkyl; unsubstituted (C1-C10)alkyl; unsubstituted (C1-C5)alkyl; methyl; ethyl; 1-propyl; 2-propyl; 1-butyl; 2-butyl; 2-methylpropyl; 1,1-dimethylethyl; 1-pentyl; 1-hexyl; 1-heptyl; 1-nonyl; and 1-decyl. Examples of substituted (C1-C40)alkyl are substituted (C1-C20)alkyl, substituted (C1-C10)alkyl, trifluoromethyl, and (C45)alkyl. The (C45)alkyl is, for example, a (C27-C40)alkyl substituted by one Rs, which is a (C₁-C₅)alkyl, respectively. In some embodiments, each (C₁-C₅)alkyl independently is methyl, trifluoromethyl, ethyl, 1-propyl, 1-methylethyl, or 1,1-dimethylethyl, for example.

The term “(C6-C40) aryl” can refer to an unsubstituted or substituted (by one or more Rs) mono-, bi-, or tricyclic aromatic hydrocarbon radical of from 6 to 40 carbon atoms, of which at least from 6 to 14 of the carbon atoms are aromatic ring carbon atoms, and the mono-, bi-, or tricyclic radical comprises 1, 2 or 3 rings, respectively; wherein the 1 ring is aromatic and the 2 or 3 rings independently are fused or non-fused and at least one of the 2 or 3 rings is aromatic. Examples of unsubstituted (C6-C40) aryl are: unsubstituted (C6-C20) aryl unsubstituted (C6-C18) aryl; 2-(C₁-C₅)alkyl-phenyl; 2,4-bis(C₁-C₅)alkyl-phenyl; phenyl; fluorenyl; tetrahydrofluorenyl; indacenyl; hexahydroindacenyl; indenyl; dihydroindenyl; naphthyl; tetrahydronaphthyl; and phenanthrene. Examples of substituted (C6-C40) aryl are: substituted (C1-C20) aryl; substituted (C6-C18) aryl; 2,4-bis[(C20)alkyl]-phenyl; polyfluorophenyl; pentafluorophenyl; and fluoren-9-one-1-yl.

The term “(C3-C40) cycloalkyl” can refer to a saturated cyclic hydrocarbon radical of from 3 to 40 carbon atoms that is unsubstituted or substituted by one or more Rs. Other cycloalkyl groups (e.g., (C3-C12)alkyl) can be defined in an analogous manner. Examples of unsubstituted (C3-C40) cycloalkyl are: unsubstituted (C3-C20) cycloalkyl, unsubstituted (C3-C10) cycloalkyl, cyclopropyl, cyclobutyl, cyclopentyl, cyclohexyl, cycloheptyl, cyclooctyl, cyclononyl, and cyclodecyl. Examples of substituted (C3-C40) cycloalkyl are: substituted (C3-C20) cycloalkyl, substituted (C3-C10) cycloalkyl, cyclopentanon-2-yl, and 1-fluorocyclohexyl.

Examples of (C1-C40) hydrocarbylene are: unsubstituted or substituted (C6-C40) arylene, (C3-C40) cycloalkylene, and (C1-C40)alkylene (e.g., (C1-C20)alkylene). In some embodiments, the diradicals are a same carbon atom (e.g., —CH2-) or on adjacent carbon atoms (i.e., 1,2-diradicals), or are spaced apart by one, two, or more intervening carbon atoms (e.g., respective 1,3-diradicals, 1,4-diradicals, etc.), for example. Some embodiments incorporate a 1,2-, 1,3-, 1,4-, or an alpha, omega-diradical, and others a 1,2-diradical, for example. The alpha, omega-diradical can be a diradical that has maximum carbon backbone spacing between the radical carbons. Some embodiments can incorporate a 1,2-diradical, 1,3-diradical, or 1,4-diradical version of (C6-C18) arylene, (C3-C20) cycloalkylene, or (C2-C20)alkylene.

The term “(C1-C40)alkylene” can refer to a saturated straight chain or branched chain diradicals (i.e., the radicals are not on ring atoms) of from 1 to 40 carbon atoms that is unsubstituted or substituted by one or more Rs. Examples of unsubstituted (C1-C40)alkylene are: unsubstituted (C1-C20)alkylene, including unsubstituted 1,2-(C2-C10)alkylene; including unsubstituted 1,3-(C3-C10)alkylene; 1,4-(C4-C10)alkylene; —C—, —CH2CH2-, —(CH2)-, —CH2CHCH3, —(CH2) 4-, —(CH2)5-, —(CH2)6-, —(CH2)7-, —(CH2)8-, and —(CH2)4C(H)(CH3)-. Examples of substituted (C1-C40)alkylene are: substituted (C1-C20)alkylene, —CF2-, —C(O)—, and —(CH2)14C(CH3)2(CH2)5- (i.e., a 6,6-dimethyl substituted normal-1,20-eicosylene). As mentioned previously two Rs may be taken together to form a (C1-C18)alkylene, examples of substituted (C1-C40)alkylene also include 1,2-bis(methylene)cyclopentane, 1,2-bis(methylene)cyclohexane, 2,3-bis(methylene)-7,7-dimethyl-bicyclo[2.2.1]heptane, and 7,3-bis(methylene) bicyclo[2.2.2]octane.

The term “(C3-C40) cycloalkylene” can refer to a cyclic diradical (i.e., the radicals are on ring atoms) of from 3 to 40 carbon atoms that is unsubstituted or substituted by one or more Rs.

The term “heteroatom,” “heterohydrocarbon’ can refer to a molecule or molecular framework in which one or more carbon atoms are replaced with an atom other than carbon or hydrogen. The term “(C1-C40) heterohydrocarbyl” can refer to a heterohydrocarbon radical of from 1 to 40 carbon atoms and the term “(C1-C40) heterohydrocarbylene” can refer to a heterohydrocarbon diradical of from 1 to 40 carbon atoms, and each heterohydrocarbon independently has one or more heteroatoms, for example O, S, S(O), S(O)₂, Si(RC)₂, P(RP), and N(RN). Independently each RC is unsubstituted (C1-C18) hydrocarbyl, each RP is unsubstituted (C1-C19) hydrocarbyl, and each RN is unsubstituted (C1-C18) hydrocarbyl or absent. When RN is absent then N comprises —N═. The heterohydrocarbon radical, and each of the heterohydrocarbon diradicals, independently is on a carbon atom or heteroatom thereof, and in most embodiments, it is on a carbon atom when bonded to a heteroatom formula (I) or to a heteroatom of another heterohydrocarbyl or heterohydrocarbylene. Each (C1-C40) heterohydrocarbyl and (C1-C40) heterohydrocarbylene independently is unsubstituted or substituted (by one or more Rs), aromatic or non-aromatic, saturated or unsaturated, straight chain or branched chain, cyclic (including mono- and poly-cyclic, fused and non-fused polycyclic) or acyclic, or a combination of two or more thereof; and each is respectively the same as or different from another.

In some embodiments, the (C1-C40) heterohydrocarbyl independently can be unsubstituted or substituted (C1-C40) heteroalkyl, (C1-C40) hydrocarbyl-O—, (C1—C40) hydrocarbyl-S—, (C1-C40) hydrocarbyl-S(O)—, (C1-C40) hydrocarbyl-S(O)₂—, (C1-C40) hydrocarbyl-Si(Rc)₂-, (C1-C40) hydrocarbyl-N(RN)—, (C1-C40) hydrocarbyl-P(RP)—, (C2-C40) heterocycloalkyl, (C2-C19) heterocycloalkyl-(C1-C20)alkylene, (C3-C20cycloalkyl-(C1-C19) heteroalkylene, (C2-C19) heterocycloalkyl-(C1-C20) heteroalkylene, (C1-C40) heteroaryl, (C1-C19) heteroaryl-(C1-C20)alkylene, (C6-C20) aryl-(C1-C19) heteroalkylene, or (C1-C19) heteroaryl-(C1-C20) heteroalkylene, for example.

The term “(C4-C40) heteroaryl” can refer to an unsubstituted or substituted (by one or more Rs) mono-, bi-, or tricyclic heteroaromatic hydrocarbon radical of from 1 to 40 total carbon atoms and from 1 to 4 heteroatoms, and the mono-, bi-, or tricyclic radical can include 1, 2, or 3 rings, respectively, wherein the 2 or 3 rings independently can be fused or non-fused and at least one of the 2 or 3 rings can be heteroaromatic. Other heteroaryl groups (e.g., (C4-C12) heteroaryl) can be defined in an analogous manner. The monocyclic heteroaromatic hydrocarbon radical can be a 5-membered or 6-membered ring. The 5-membered ring can have from 2 to 4 carbon atoms and from 3 to 1 heteroatoms, respectively, each heteroatom being O, S, N, or P. Examples of 5-membered ring heteroaromatic hydrocarbon radical are: pyrrol-1-yl; pyrrol-2-yl; furan-3-yl; thiophen-2-yl; pyrazol-1-yl; isoxazol-2-yl; isothiazol-5-yl; imidazol-2-yl; oxazol-4-yl; thiazol-2-yl; 1,2,4-triazol-1-yl; 1,3,4-oxadiazol-2-yl; 1,3,4-thiadiazol-2-yl; tetrazol-1-yl; tetrazol-2-yl; and tetrazol-5-yl. The 6-membered ring can have 4 or 5 carbon atoms and 2 or 1 heteroatoms, the heteroatoms being N or P. Examples of 6-membered ring heteroaromatic hydrocarbon radical are: pyridine-2-yl; pyrimidin-2-yl; and pyrazin-2-yl. The bicyclic heteroaromatic hydrocarbon radical can be a fused 5,6- or 6,6-ring system. Examples of the fused 5,6-ring system bicyclic heteroaromatic hydrocarbon radical are: indol-1-yl; and benzimidazole-1-yl. Examples of the fused 6,6-ring system bicyclic heteroaromatic hydrocarbon radical are: quinolin-2-yl; and isoquinolin-1-yl. The tricyclic heteroaromatic hydrocarbon radical can be a fused 5,6,5-; 5,6,6-; 6,5,6-; or 6,6,6-ring system. An example of the fused 5,6,5-ring system is 1,7-dihydropyrrolo[3,2-f]indol-1-yl. An example of the fused 5,6,6-ring system is 1H-benzo[f]indol-1-yl. An example of the fused 6,5,6-ring system is 9H-carbazol-9-yl. An example of the fused 6,5,6-ring system is 9H-carbazol-9-yl. An example of the fused 6,6,6-ring system is acrydin-9-yl.

The aforementioned heteroalkyl and heteroalkylene groups can be saturated straight or branched chain radicals or diradicals, respectively, containing (C1-C40) carbon atoms, or fewer carbon atoms and one or more of the heteroatoms Si(Rc)₂, P(RP), N(RN), N, O, S, S(O), and S(O)₂ as defined above, wherein each of the heteroalkyl and heteroalkylene groups independently can be unsubstituted or substituted by one or more Rs.

Examples of unsubstituted (C2-C40) heterocycloalkyl are: unsubstituted (C2-C20) heterocycloalkyl, unsubstituted (C2-C10) heterocycloalkyl, aziridin-1-yl, oxetan-2-yl, tetrahydrofuran-3-yl, pyrrolidin-1-yl, tetrahydrothiophen-S,S-dioxide-2-yl, morpholin-4-yl, 1,4-dioxan-2-yl, hexahydroazepin-4-yl, 3-oxa-cycloodyl, 5-thio-cyclononyl, and 2-aza-cyclodecyl.

The term “halogen atom” can refer to fluorine atom (F), chlorine atom (Cl), bromine atom (Br), or iodine atom (I) radical. The terms “halide” can refer to fluoride (F—), chloride (Cl—), bromide (Br—), or iodide (I—) anion.

The term “saturated” can refer to lacking carbon-carbon double bonds, carbon-carbon triple bonds, and (in heteroatom-containing groups) carbon-nitrogen, carbon-phosphorous, and carbon-silicon double bonds. Where a saturated chemical group is substituted by one or more substituents Rs, one or more double and/or triple bonds optionally may or may not be present in substituents Rs. The term “unsaturated” can refer to containing one or more carbon-carbon double bonds, carbon-carbon bonds, and (in heteroatom-containing groups) carbon-nitrogen, carbon-phosphorous, and carbon-silicon double bonds, not including any such double bonds that may be present in substituents Rs, if any, or in (hetero) aromatic rings, if any.

### First Resist Composition

In an embodiment of present disclosure, a first resist composition of a first patterned resist layer 104 (see FIG. 1A) can be a composition that can include a polymer, an SSA, a first solvent, and may also contain additional, optional components. In an embodiment, when the first resist is a photoresist, the SSA comprises one or more PAGs.

### First Polymer

In an embodiment, the first polymer of the first resist composition may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the—OH group of p-hydroxystyrene may be protected with a tert-butyloxycarbonyl protecting group. Such protecting group may alter the reactivity and solubility of the polymer included in the first photoresist. As will be appreciated by one having ordinary skill in the art, various protecting groups may be used for this reason. Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group which, on decomposition, forms a carboxylic acid on the polymer is preferably a tertiary ester group of the formula —C(O)OC(R¹)s or an acetal group of the formula —C(O)OC(R²)₂OR³, wherein: R¹ is each independently linear Ci-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C 1-6 alkyl, branched C3-6 alkyl, or monocyclic or polycyclic C3-10 cycloalkyl, each of which is substituted or unsubstituted, each R¹ optionally including as part of its structure one or more groups chosen from —O—, —C(O)—, —C(O)—O—, or—S—, and any two R¹ groups together optionally forming a ring; R² is independently hydrogen, fluorine, linear C 1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably hydrogen, linear C 1-6 alkyl, branched C3-6 alkyl, or monocyclic or polycyclic C3-10 cycloalkyl, each of which is substituted or unsubstituted, each R² optionally including as part of its structure one or more groups chosen from —O—, —C(O)—, —C(O)—O—, or —S—, and the R² groups together optionally forming a ring; and R³ is linear Ci-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C&-20 aryl, or monocyclic or polycyclic C2-20 heteroaryl, preferably linear C 1-6 alkyl, branched C3-6 alkyl, or monocyclic or polycyclic C3-10 cycloalkyl, each of which is substituted or unsubstituted, R³ optionally including as part of its structure one or more groups chosen from—O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The first polymer can further include as polymerized a monomer comprising an acid-labile group, the decomposition of which group forms an alcohol group or a fluoroalcohol group on the polymer. Suitable such groups include, for example, an acetal group of the formula-COC(R²)₂OR³—, or a carbonate ester group of the formula —OC(O)O—, wherein R is as defined above. Such monomer is typically a vinyl aromatic, (meth)acrylate, or norbomyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

### Photoacid Generator

In embodiments in which the first resist is a photoresist, the first resist includes a photoacid generator (PAG). The photoacid generator is a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

A choice of PAG can be based upon such factors as acidity, catalytic activity, volatility, diffusivity, and solubility. Examples of embodied photoacid generators can include a diazonium salt, a phosphonium salt, a sulfonium salt, an iodonium salt, an imidosulfonate, an oxime sulfonate, a diazodisulfone, a disulfone, or an o-nitrobenzyl sulfonate, for example.

Suitable classes of PAGs generating sulfonic acids can include, but are not limited to, sulfonium or iodonium salts, oximidosulfonates, bissulfonyldiazomethanes, and nitrobenzylsulfonate esters, for example. A PAG can be in non-polymerized or polymeric form, for example, present in a polymerized repeating unit of the polymer matrix. Suitable photoacid generator compounds are disclosed, for example, in U.S. Pat. Nos. 5,558,978, 5,468,589, 6,844,132, 6,855,476, and 6,911,297, which are incorporated herein by reference in their entireties. In some embodiments, a preferred PAGs can include one or more of tris(perfluoroalkylsulfonyl) methides, tris(perfluoroalkylsulfonyl)imides, and those generating perfluoroalkylsulfonic acids, for example.

Additional examples of suitable photoacid generators can include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl) sulfonium perfluorooctanesulfonate, tris(-t-butylphenyl) sulfonium perfluorobutanesulfonate, tris(-t-butylphenyl) sulfonium 2,4,6-triisopropylbenzenesulfonate, tris(-t-butylphenyl) sulfonium benzenesulfonate, and phenylthiophenyldiphenylsulfonium perfluorooctanesulfonate.

Examples of suitable iodonium salts can include, but are not limited to, diphenyl iodonium perfluorobutanesulfonate, bis-(t-butylphenyl) iodonium perfluorobutanesulfonate, bis-(t-butylphenyl) iodonium, perfluorooctanesulfonate, diphenyl iodonium perfluorooctanesulfonate, bis-(t-butylphenyl) iodonium benzenesulfonate, bis-(t-butylphenyl) iodonium 2,4,6-triisopropylbenzenesulfonate, and diphenyliodonium 4-methoxybenzensulfonate.

Examples of tris(perfluoroalkylsulfonyl) methide and tris(perfluoroalkylsulfonyl)imide PAGs can be found in U.S. Pat. Nos. 5,554,664 and 6,306,555, each of which is incorporated herein in its entirety. For an SSA 114 of an embodiment, additional examples of PAGs of this type can be found in Proceedings of SPIE, Vol. 4690, pp. 817-828 (2002).

Suitable methide and imide PAGs can include, but are not limited to, triphenylsulfonium tris(trifluoromethylsulfonyl) methide, methylphenyldiphenylsulfonium tris(perfluoroethylsulfonyl) methide, triphenylsulfonium tris(perfluorobutylsulfonyl) methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

Further examples of suitable photoacid generators can be bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl) propiophenone, 2-methanesulfonyl-2-methyl-(4-methylthiopropiophenone, 2,4-methyl-2-(p-toluenesulfonyl) pent-3-one, 1-diazo-1-methylsulfonyl-4-phenyl-2-butanone, 2-(cyclohexylcarbonyl-2-(p-toluenesulfonyl) propane, 1-cyclohexylsulfonyl-1cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate.

Some more preferred PAGs can be triarylsulfonium perfluoroalkylsulfonates and triarylsulfonium tris(perfluoroalkylsulfonyl) methides. For an SSA 114 of an embodiment, some more preferred PAGs can include triphenylsulfonium perfluorooctanesulfonate (TPS-PFOS), triphenylsulfonium perfluorobutanesulfonate (TPS-Nonaflate), methyiphenyldiphenylsulfonium perfluorooctanesulfonate (TDPS-PFOS), tris(-t-butylphenyl) sulfonium perfluorobutanesulfonate (TTBPS-Nonaflate), triphenylsulfonium tris(trifluoromethylsulfonyl) methide (TPS-C1), or methylphenyldiphenylsulfonium tris(perfluoroethylsulfonyl) methide.

Additional PAG compounds can include, for example: onium salts, for example, triphenylsulfonium trifluoromethanesulfonate, (p-tert-butoxyphenyl)diphenylsulfonium trifluoromethanesulfonate, tris(p-tert-butoxyphenyl) sulfonium trifluoromethanesulfonate, triphenylsulfonium p-toluenesulfonate; di-t-butyphenyliodonium perfluorobutanesulfonate, or di-t-butyphenyliodonium camphorsulfonate.

Non-ionic sulfonates and sulfonyl compounds can function as photoacid generators, for example: nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; or halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Suitable non-polymerized photoacid generators that can be used are further described in U.S. Pat. No. 8,431,325 to Hashimoto et al. in column 37, lines 11-47 and columns 41-91. For an SSA 114 of an embodiment, other suitable sulfonate PAGs can include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically can include an anion having a sulfonate group or a non-sulfonate type group, such as a sulfonamidate group, a sulfonimidate group, a methide group, or a borate group.

In an embodiment, a first resist composition may optionally include a plurality of PAGs. The plural PAGs can be polymeric, non-polymeric, or can include both polymeric and non-polymeric PAGs. In some embodiments, each of the plurality of PAGs can be non-polymeric. In some embodiments, when a plurality of PAGs are used, a first PAG can include a sulfonate group on the anion and a second PAG can include an anion that is free of sulfonate groups, such anion containing for example, a sulfonamidate group, a sulfonimidate group, a methide group, or a borate group, such as described above, for example.

In some embodiments, the PAG can be a polymeric PAG, wherein the compound capable of generating an acid upon irradiation with actinic rays or radiation is introduced into the main or side chain of the polymer. Examples can include, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853, and JP-A-63-146029.

### Optional Additives

In some embodiments, the first resist optionally contains other additives, wherein other additives include at least one of a resin having at least either a fluorine atom or a silicon atom, a basic compound, a surfactant, an onium carboxylate, dye, a plasticizer, a photosensitizer, a light absorbent, an alkali-soluble resin, a dissolution inhibitor, and a compound for accelerating dissolution in a developer.

### Overcoat Comprising Solubility Shifting Agent

In an embodiment of present disclosure, a composition of an overcoat 110 (see FIG. 1B) can be a composition that can include a second polymer, an SSA 114 (see FIG. 1B), a solvent, and may also contain additional, optional components.

### Second Polymer

In some embodiments, the second polymer may include a matrix polymer. Any matrix polymer commonly used in the art may be included in the solubility-shifting material. The matrix polymer should have good solubility in a solvent that does not dissolve the first resist. The matrix polymer can be formed from one or more monomers chosen, for example, from those having an ethylenically unsaturated polymerizable double bond, such as: (meth)acrylate monomers such as isopropyl (meth)acrylate and n-butyl (meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbornenes; and combinations thereof.

In some embodiments, the second polymer contains one or more functional groups chosen, for example, from hydroxy, acid groups such as carboxyl, sulfonic acid and sulfonamide, silanol, fluoroalcohol such as hexafluoroisopropyl alcohol [—C(CF3)2OH], anhydrates, lactones, esters, ethers, allylamine, pyrrolidones and combinations thereof. The second polymer can be a homopolymer or a copolymer having a plurality of distinct repeat units, for example, two, three, four or more distinct repeat units. In one aspect, the repeat units of the second polymer are all formed from (meth)acrylate monomers, are all formed from (vinyl) aromatic monomers or are all formed from (meth)acrylate monomers and (vinyl) aromatic monomers. When the second polymer includes more than one type of repeat unit, it typically takes the form of a random copolymer.

In particular embodiments, the matrix polymer may be a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, a PHS/methacrylate (MA) copolymer, and combinations thereof.

The overcoat compositions typically include a single polymer but can optionally include one or more additional polymers. The content of the second polymer in the composition will depend, for example, on the target thickness of the layer, with a higher polymer content being used when a thicker layer is desired. The second polymer is typically present in the overcoat composition in an amount of from 80 to 99.9 wt %, more typically from 90 to 99 wt %, or 95 to 99 wt %, based on total solids of the overcoat compositions. The weight average molecular weight (Mw) of the polymer is typically less than 400,000, preferably from 3000 to 50,000, more preferably from 3000 to 25,000, as measured by GPC versus polystyrene standards. Typically, the second polymer will have a polydispersity index (PDI=Mw/Mn) of 3 or less, preferably 2 or less, as measured by GPC versus polystyrene standards.

Suitable second polymers for use in the overcoat compositions are commercially available and/or can readily be made by persons skilled in the art. For example, the second polymer may be synthesized by dissolving selected monomers corresponding to units of the second polymer in an organic solvent, adding a radical polymerization initiator thereto, and effecting heat polymerization to form the polymer. Examples of suitable organic solvents that can be used for polymerization of the polymer include, for example, toluene, benzene, tetrahydro-furan, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

In one or more embodiments, an overcoat composition includes an active material (z.e., an acid, acid generator, base, or base generator), a solvent, and a matrix polymer as previously described. A typical formulation for such overcoat composition may include about 1 to 10 wt % solids and 90 to 99 wt % solvent, based on the total weight of the overcoat composition, where the solids include the active material and the matrix polymer. Within the solids content, the active material may be included in an amount ranging from about 1 to about 5 wt %.

### Solubility Shifting Agent

Next, some example materials that can be implemented and used for a solubility shifting agents (SSA) 114 referenced above while describing the example embodiments of FIGS. 1A-1H, will be described.

In an embodiment, an SSA 114 can include an acid or an acid generator such as a TAG or PAG, for example. In an embodiment, the SSA 114 can include multiple solubility shifting agents combined, such as multiple PAGs, multiple TAGs, or one or more PAGs combined with one or more TAGS, or any combination thereof with an already free acid, for example. In another embodiment, an SSA 114 can include a base or a base generator.

### Solubility Shifting Agent as Free Acid

In some embodiments, the SSA 114 can be an acid that is an organic acid, which can include both non-aromatic acids and aromatic acids optionally having fluorine substitution. Suitable organic acids for the SSA 114 of an embodiment can include: carboxylic acids and polycarboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid, and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid; or any combination thereof, for example.

In some embodiments, an SSA 114 can be an aromatic sulfonic acid. For example, an aromatic sulfonic acid can be of general Formula 4:

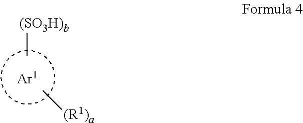

In Formula 4, Ar¹ can represent an aromatic group, which can be carbocyclic, heterocyclic, or a combination thereof. The aromatic group can be monocyclic, for example, phenyl or pyridyl, or polycyclic, for example biphenyl, and can include: plural fused aromatic rings such as naphthyl, anthracenyl, pyrenyl, or quinolinyl; or fused ring systems having both aromatic and non-aromatic rings such as 1,2,3,4-tetrahydronaphthalene, 9,10-dihydroanthracene or fluorene. A wide variety of aromatic groups may be used for Ar¹. The aromatic group typically can have from 5 to 40 carbons, preferably from 6 to 35 carbons, and more preferably from 6 to 30 carbons. Suitable aromatic groups can include, but are not limited to: phenyl, biphenyl, naphthalenyl, anthracenyl, phenanthrenyl, pyrenyl, tetracenyl, triphenylenyl, tetraphenyl, benzo[f]tetraphenyl, benzo[m]tetraphenyl, benzo[k]tetraphenyl, pentacenyl, perylenyl, benzo[a]pyrenyl, benzo[e]pyrenyl, benzo[ghi]perylenyl, coronenyl, quinolonyl, 7,8-benzoquinolinyl, fluorenyl, and 12H-dibenzo[b,h]fluorenyl. Of these, phenyl can be particularly preferred.

In Formula 4, R¹ independently can represent a halogen atom, hydroxy, substituted or unsubstituted alkyl, substituted or unsubstituted heteroalkyl, substituted or unsubstituted carbocyclic aryl, substituted or unsubstituted heterocyclic aryl, substituted or unsubstituted alkoxy, or a combination thereof. R¹ can also include one or more groups such as ester, carboxy, ether, or a combination thereof.

In Formula 4, “a” can represent an integer of 0 or more and “b” can represent an integer of 1 or more, provided that a+b is not greater than the total number of available aromatic carbon atoms of Ar¹. Preferably, two or more of R¹ can be independently a fluorine atom or a fluoroalkyl group bonded directly to an aromatic ring carbon atom.

The aromatic acid can be a sulfonic acid including a phenyl, biphenyl, naphthyl, anthracenyl, thiophene or furan group. The aromatic acid can be chosen from one or more aromatic sulfonic acids of the following general Formulas 5-10:

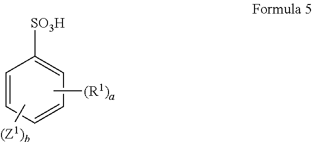

In Formula 5, R¹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 5, Z¹ can independently represent a group chosen from carboxyl, hydroxy, nitro, cyano, C1 to C5 alkoxy, formyl and sulfonic acid. In Formula 5, “a” and “b” can be independently an integer from 0 to 5, and a+b can be 5 or less.

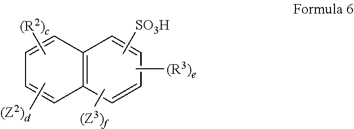

In Formula 6, R² and R³ each can independently represent a substituted or unsubstituted C1-C20 alkyl group, a substituted or unsubstituted C5-C16 aryl group, or a combination thereof, optionally containing one or more group chosen from carbonyl, carbonyloxy, sulfonamido, ether, thioether, a substituted or unsubstituted alkylene group, or a combination thereof.

In Formula 6, Z² and Z³ each can independently represent a group chosen from carboxyl, hydroxy, nitro, cyano, C1 to C5 alkoxy, formyl and sulfonic acid. In Formula 6, “c” and “d” can be independently an integer from 0 to 4, c+d can be 4 or less, “e” and “f” can be independently an integer from 0 to 3, and e+f can be 3 or less.

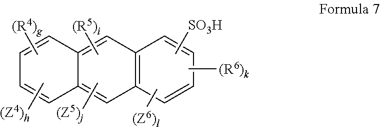

In Formula 7, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof

In Formula 7, Z⁴, Z⁵ and Z⁶ each can independently represent a group chosen from carboxyl, hydroxy, nitro, cyano, C1 to C5 alkoxy, formyl and sulfonic acid. In Formula 7, “g” and “h” can be independently an integer from 0 to 4, g+h can be 4 or less, “i” and “j” can be independently an integer from 0 to 2, i+j can be 2 or less, “k” and “1” can be independently an integer from 0 to 3, and k+1 can be 3 or less.

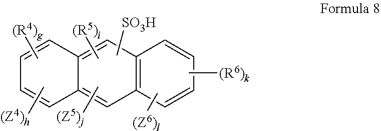

In Formula 8, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof.

In Formula 8, Z⁴, Z⁵ and Z⁶ each can independently represent a group chosen from carboxyl, hydroxy, nitro, cyano, C1 to C5 alkoxy, formyl and sulfonic acid. In Formula 8, “g” and “h” can be independently an integer from 0 to 4, g+h can be 4 or less, “i” and “j” can be independently an integer from 0 to 1, i+j can be 1 or less, “k” and “1” can be independently an integer from 0 to 4, and k+1 can be 4 or less.

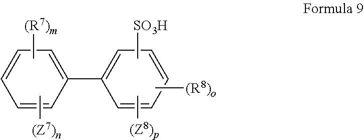

In Formula 9, R7 and R8 each can independently represent a substituted or unsubstituted C1-C20 alkyl group, a substituted or unsubstituted C5-C14 aryl group, or a combination thereof, optionally containing one or more group chosen from carboxyl, carbonyl, carbonyloxy, sulfonamido, ether, thioether, a substituted or unsubstituted alkylene group, or a combination thereof

In Formula 9, Z⁷ and Z⁸ each can independently represent a group chosen from hydroxy, nitro, cyano, C1 to C5 alkoxy, formyl and sulfonic acid. In Formula 9, “m” and “n” can be independently an integer from 0 to 5, m+n can be 5 or less, “o” and “p” can be independently an integer from 0 to 4, and o+p can be 4 or less.

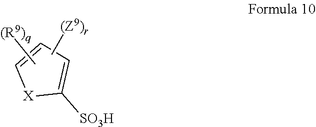

In Formula 10, X can be O or S. In Formula 10, R⁹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 10, Z⁹ can independently represent a group chosen from carboxyl, hydroxy, nitro, cyano, C1 to C5 alkoxy, formyl and sulfonic acid. In Formula 10, “q” and “r” can be independently an integer from 0 to 3, and q+r can be 3 or less.

For each of the structures of Formulas 5-10, the R¹-R⁹ groups can optionally form a fused structure together with their respective associated rings, for example.

For an SSA 114 of an embodiment, example aromatic sulfonic acids can include, without limitation, the following:

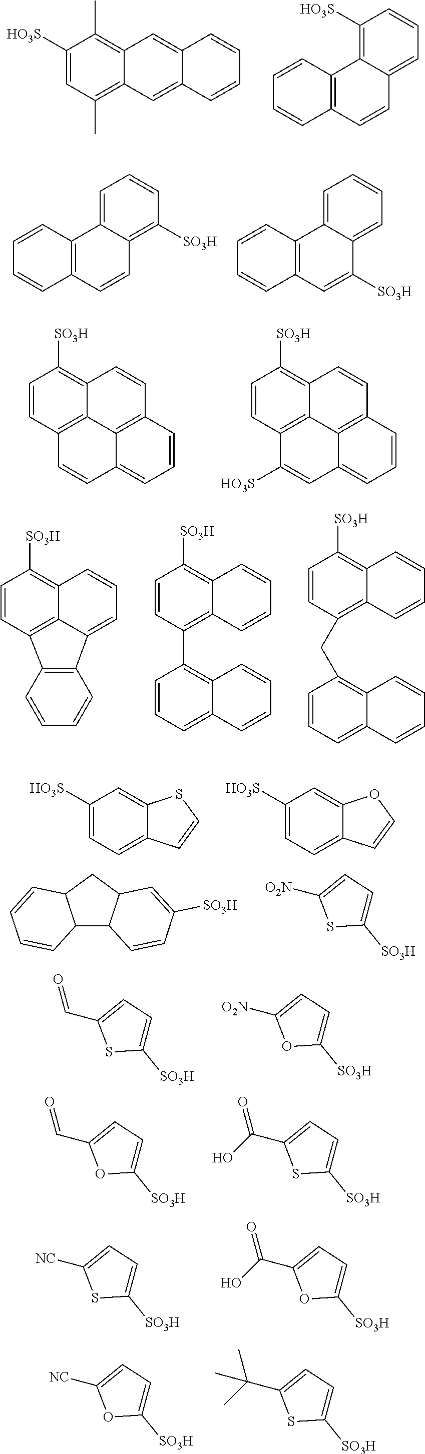

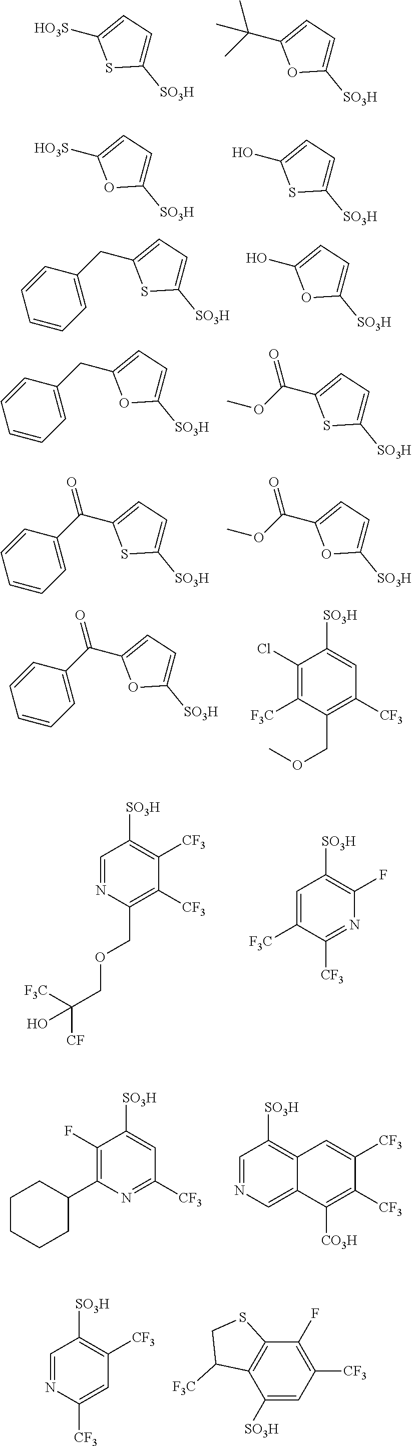

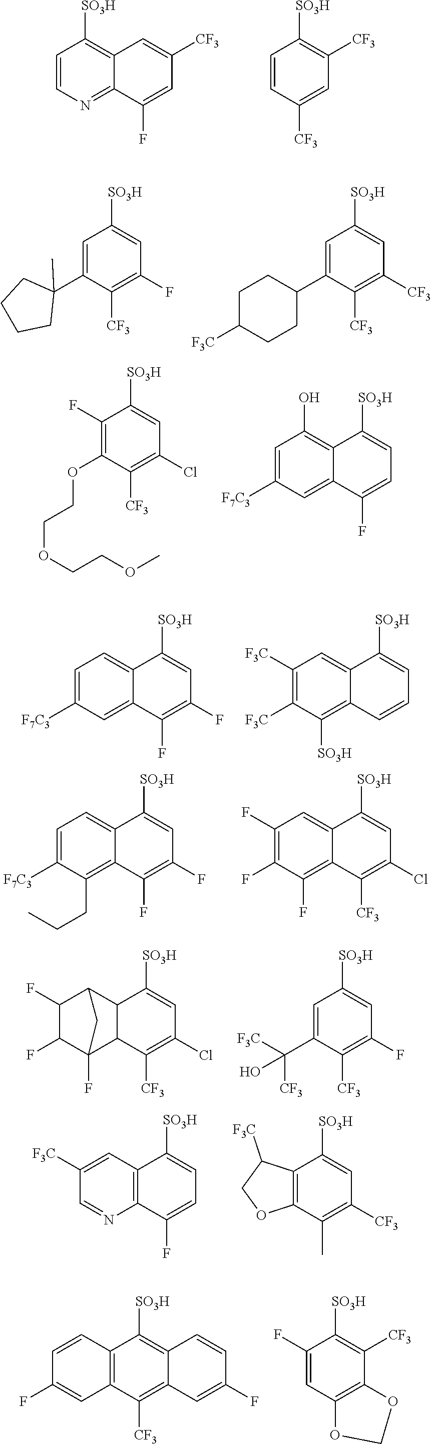

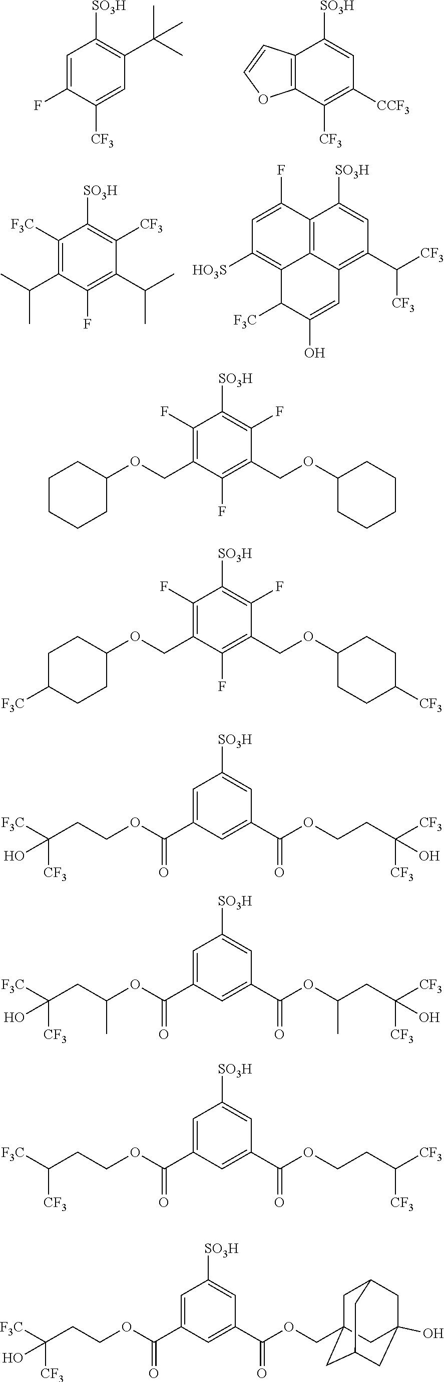

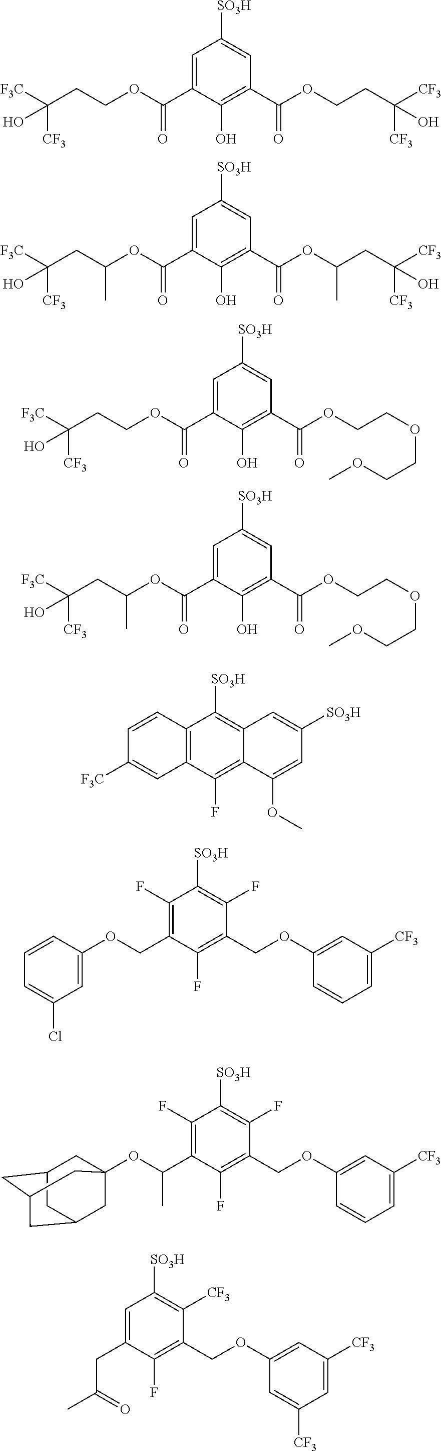

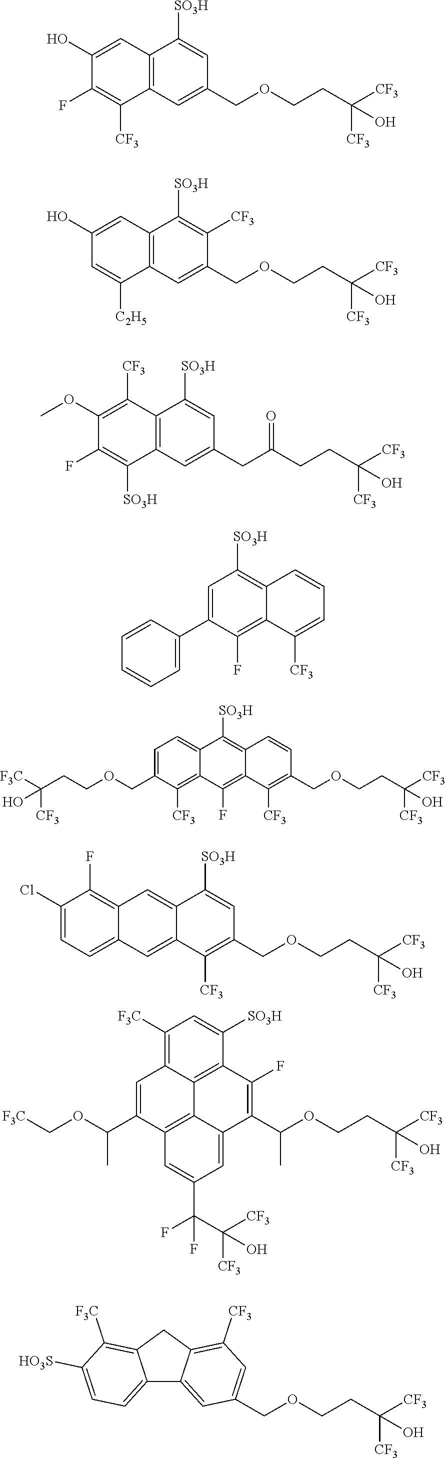

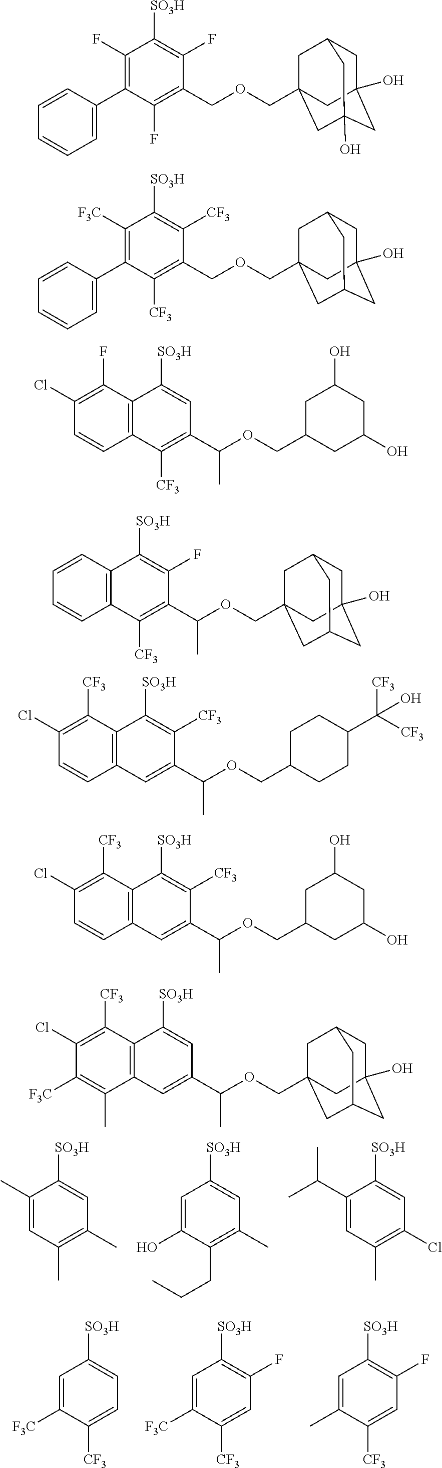

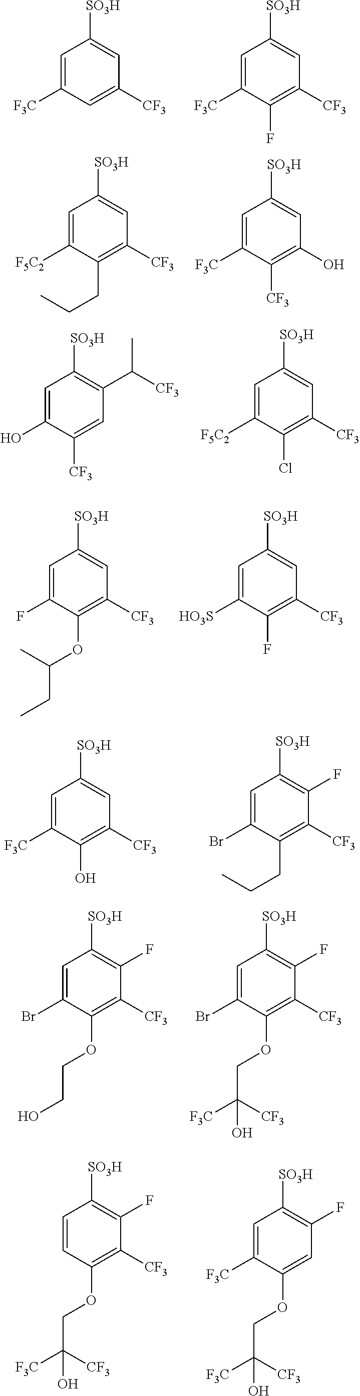

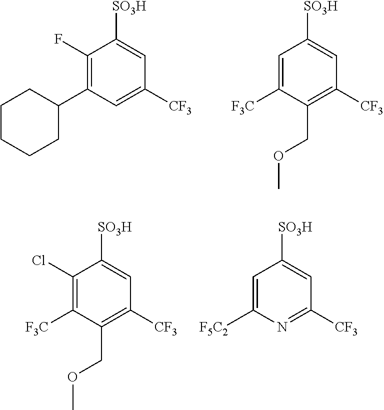

For an SSA 114 of an embodiment, example non-aromatic sulfonic acids can include, without limitation, the following:

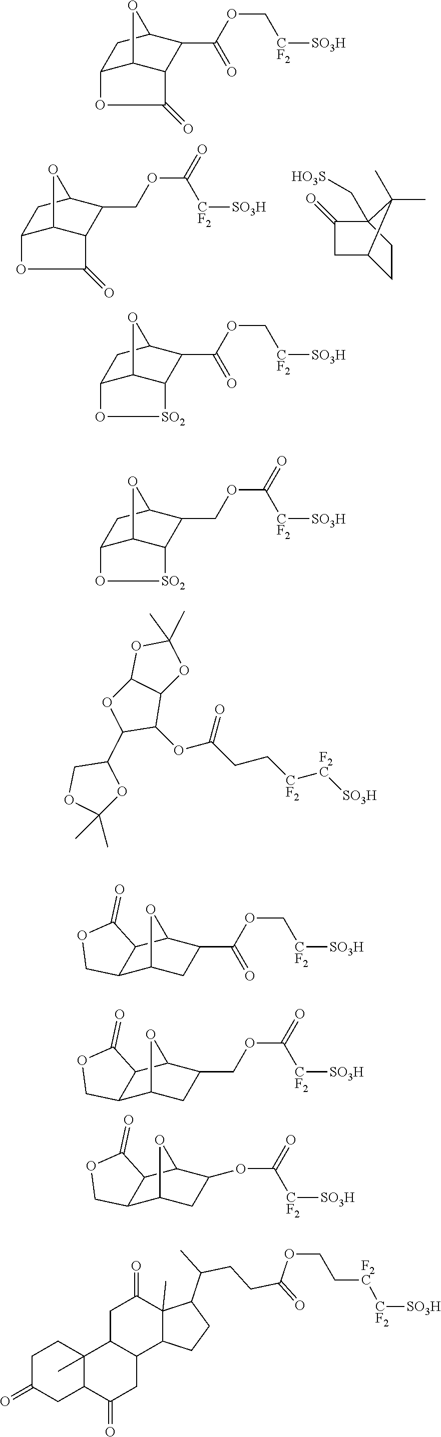

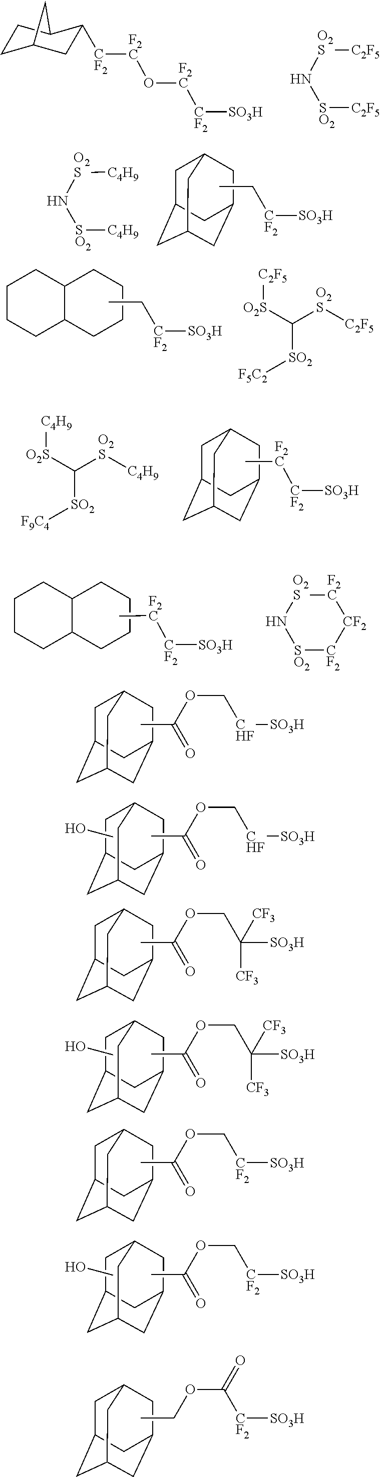

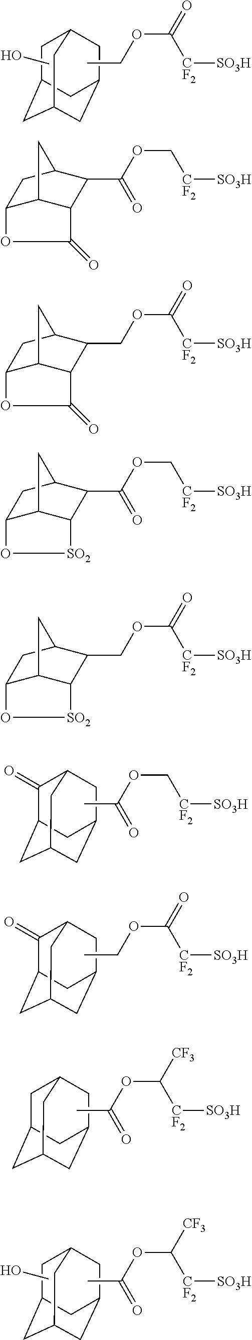

### Solubility Shifting Agent as Thermal Acid Generator (TAG)

For an SSA 114 of an embodiment, suitable thermal acid generators can include those capable of generating the acids described above. The thermal acid generator (TAG) can be non-ionic or ionic.

For an SSA 114 of an embodiment, suitable nonionic thermal acid generators can include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1, 3, 5-triazine-2, 4, 6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, or their salts, or combinations thereof.

For an SSA 114 of an embodiment, suitable ionic thermal acid generators can include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, or benzenesulfonate salts, or combinations thereof. Compounds that can generate a sulfonic acid upon activation can be generally suitable as a TAG for an SSA 114 of an embodiment, for example. For an SSA 114 of an embodiment, some preferred thermal acid generators can include p-toluenesulfonic acid ammonium salts and heteroaryl sulfonate salts, for example.

For example, for an SSA 114 of an embodiment, the TAG can be preferably ionic with a reaction scheme for generation of a sulfonic acid as shown below:

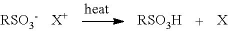

wherein RSO₃⁻ can be the TAG anion and X⁺ can be the TAG cation, preferably an organic cation.

The cation can be a nitrogen-containing cation of the general Formula 11:

(BH)⁺ Formula 11

Formula 11 can be the monoprotonated form of a nitrogen-containing base B. In Formula 11, suitable nitrogen-containing bases B can include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; and nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B can be preferably a heteroaromatic base.

Base B typically can have a pKₐ from 0 to 5.0, or between 0 and 4.0, or between 0 and 3.0, or between 1.0 and 3.0. As used herein, the term “pKₐ” is used in accordance with its art-recognized meaning, that is, pKₐ can be the negative log (to the base 10) of the dissociation constant of the conjugate acid (BH)⁺ of the basic moiety (B) in aqueous solution at about room temperature. In certain embodiments, base B can have a boiling point less than about 170° C., or less than about 160° C., 150° C., 140° C., 130° C., 120° C., 110° C., 100° C., or 90° C.

For an SSA 114 of an embodiment, example suitable nitrogen-containing cations (BH)⁺ can include NH₄⁺, CF₂HNH₂⁺, CF₃CH₂NH₃⁺, (CH₃)₃NH⁺, (C₂H₅)₃NH⁺, (CH³)₂(C₂H₅)NH⁺ and the following:

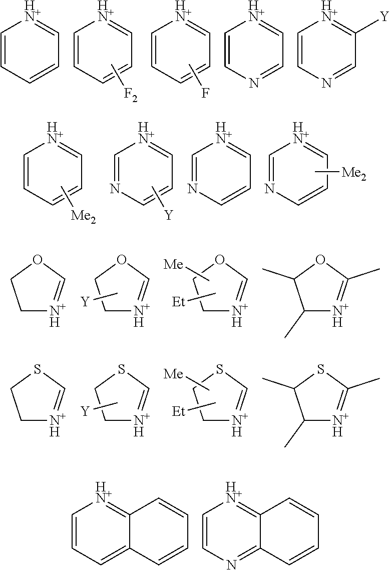

in which Y is alkyl, preferably, methyl or ethyl.

Other suitable cations can include onium cations. Suitable onium cations can include, for example, sulfonium and iodonium cations, for example, those of the following general Formula 12:

⁺X—(R¹⁰)ₛ Formula 12

In Formula 12, X can be S or I, wherein when X is I then “a” can be 2, and when X is S then “a” can be 3. In Formula 12, R¹⁰ can be independently chosen from organic groups such as optionally substituted C₁₋₃₀ alkyl, polycyclic or monocyclic C₃₋₃₀ cycloalkyl, polycyclic or monocyclic C₆₋₃₀ aryl, or a combination thereof, wherein when X is S, two of the R groups together optionally form a ring.

For an SSA 114 of an embodiment, example suitable sulfonium and iodonium cations include the following:

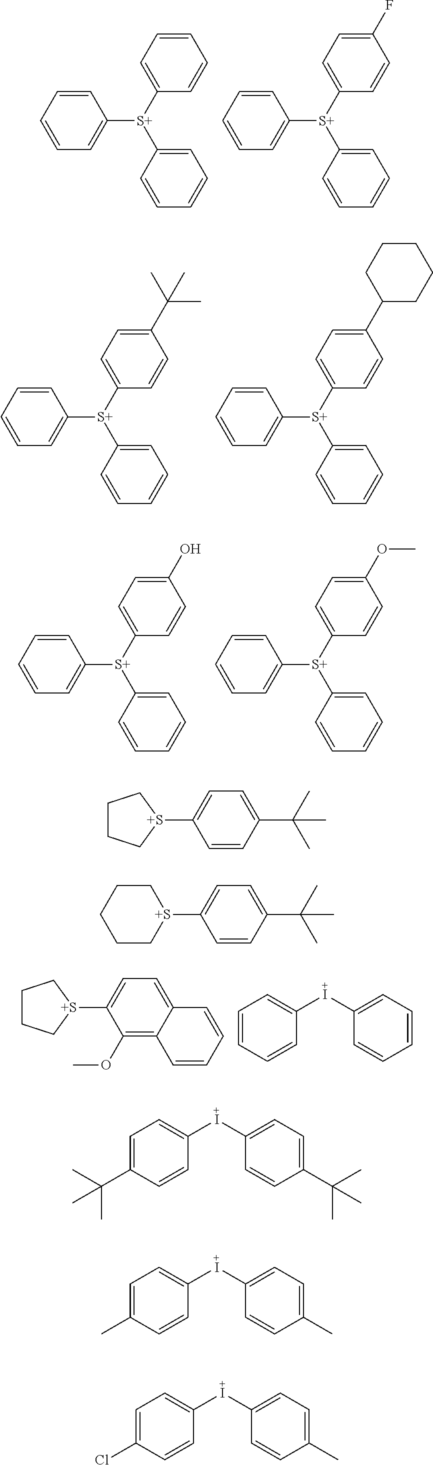

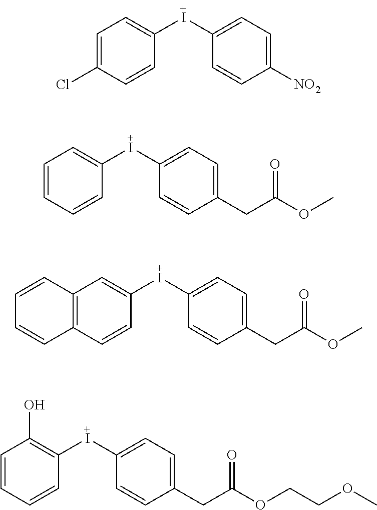

### Solubility Shifting Agent as Photoacid Generator (PAG)

For an SSA of an embodiment, suitable photoacid generators can include those described above in the first resist description.

In some embodiments, an overcoat composition can include a non-polymerized photoacid generator in an amount from about 1 to 65 wt %, from about 5 to 55 wt %, or from about 8 to 30 wt %, based on total solids of the photoresist composition, for example. In some embodiments, an overcoat composition can include two or more different non-polymerized photoacid generators in a combined amount from about 1 to 65 wt %, from about 5 to 55 wt %, or from about 8 to 30 wt %, based on total solids of the composition, for example. In some embodiments, a photoacid generator mixture can include two or three photoacid generators. Such mixtures can be of a same class or different classes. Examples of some preferred mixtures can include sulfonium salts with bis-sulfonyldiazomethane compounds, sulfonium salts and imidosulfonates, and two sulfonium salts, for example.

### Solubility Shifting Agent as Base or Base Generator

For an embodiment, suitable quencher base or base generators can include, but are not limited to, hydroxides, carboxylates, amines, imines, amides, or mixtures thereof. Specific examples of bases can include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, or combinations thereof. Amines can include aliphatic amines, cycloaliphatic amines, aromatic amines, or heterocyclic amines. The amine can be a primary, secondary, or tertiary amine. The amine can be a monoamine, diamine, or polyamine. Suitable amines can include C1-30 organic amines, imines, or amides, or may be a C1-30 quaternary ammonium salt of a strong base (e.g., a hydroxide or alkoxide) or a weak base (e.g., a carboxylate). In some embodiments, example bases can include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl) propane, Troger's base, a hindered amine such as diazabicycloundecene (DBU) or diazabicyclononene (DBN), amides like tert-butyl 1,3-dihydroxy-2-(hydroxymethyl) propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate.

In some embodiments, the amine can be a hydroxyamine. Examples of hydroxyamines can include hydroxyamines having one or more hydroxyalkyl groups each having 1 to about 8 carbon atoms, and sometimes preferably 1 to about 5 carbon atoms such as hydroxymethyl, hydroxyethyl and hydroxybutyl groups. Specific examples of hydroxy amines can include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol, and triethanolamine.

In an embodiment, suitable base generators can be thermal base generators. A thermal base generator (TAG) can form a base upon heating above a first temperature, typically about 140° C. or higher. The thermal base generator can include a functional group such as an amide, sulfonamide, imide, imine, O-acyl oxime, benzoyloxycarbonyl derivative, quarternary ammonium salt, nifedipine, carbamate, or combinations thereof, for example.

In an embodiment, example thermal base generators can include: o-{(.beta.-(dimethylamino)ethyl)aminocarbonyl}benzoic acid, o-{(.gamma.-(dimethylamino) propyl)aminocarbonyl}benzoic acid, 2,5-bis{(.beta.-(dimethylamino)ethyl)aminocarbonyl}terephthalic acid, 2,5-bis{(.gamma.-(dimethylamino) propyl)aminocarbonyl}terephthalic acid, 2,4-bis {(.beta.-(dimethylamino)ethyl)aminocarbonyl}isophthalic acid, 2,4-bis{(.gamma.-(dimethylamino) propyl)aminocarbonyl]isophthalic acid, or combinations thereof, for example.

### Solvents

As described above, in some embodiments the SSA 114 is absorbed into the first relief pattern. Accordingly, the solvent may be any suitable solvent that may facilitate absorption into the first relief pattern, provided that it does not dissolve the first resist. The solvent is typically chosen from water, organic solvents and mixtures thereof. In some embodiments, the solvent may include an organic-based solvent system comprising one or more organic solvents. The term “organic-based” means that the solvent system includes greater than 50 wt % organic solvent based on total solvents of the overcoat composition, more typically greater than 90 wt %, greater than 95 wt %, greater than 99 wt % or 100 wt % organic solvents, based on total solvents of the overcoat compositions. The solvent component is typically present in an amount of from 90 to 99 wt % based on the overcoat composition.

Suitable organic solvents for the overcoat composition include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C4-C9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C5-C9 fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; and mixtures containing one or more of these solvents.

The solvent included in the overcoat composition may depend on the composition and tone of the first resist. When the first resist is formed from a (meth)acrylate polymer, as is typical for ArF resists, and the resist is developed as a PTD resist, the solvent system preferably comprises one or more polar organic solvents. For example, a solubility-shifting agent meant to be absorbed into a PTD first resist may include a polar solvent such as methyl isobutyl carbinol (MIBC). The overcoat composition may also include aliphatic hydrocarbons, esters, and ethers as cosolvents such as, for example, decane, isobutyl isobutyrate, isoamyl ether, and combinations thereof. In particular embodiments, the solvent includes MIBC and a cosolvent. In such embodiments, the MIBC may be included in the solvent in an amount ranging from 60 to 99%, based on the total volume of solvent. Accordingly, the cosolvent may be included in an amount ranging from 1 to 40%, based on the total volume of solvent.

When the first resist is formed from a vinyl aromatic-based polymer, as is typical for KrF and EUV photoresists, and the resist is developed as a PTD resist, the solvent system preferably comprises one or more non-polar organic solvents. The term “non-polar organic-based” means that the solvent system includes greater than 50 wt % of combined non-polar organic solvents based on total solvents of the overcoat composition, more typically greater than 70 wt %, greater than 85 wt % or 100 wt %, combined non-polar organic solvents, based on total solvents of the overcoat composition. The non-polar organic solvents are typically present in the solvent system in a combined amount of from 70 to 98 wt %, preferably 80 to 95 wt %, more preferably from 85 to 98 wt %, based on the solvent system.

Suitable non-polar solvents include, for example, ethers, hydrocarbons, and combinations thereof, with ethers being preferred. Suitable ether solvents include, for example, alkyl monoethers and aromatic monoethers, particularly preferred of which are those having a total carbon number of from 6 to 16. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3, 3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

In some embodiments, the solvent system further includes one or more alcohol and/or ester solvents. For certain compositions, an alcohol and/or ester solvent may provide enhanced solubility with respect to the solid components of the composition. Suitable alcohol solvents include, for example: straight, branched or cyclic C4-9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C5-9 fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C4-9 monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent system are typically present in a combined amount of from 2 to 50 wt %, more typically in an amount of from 2 to 30 wt %, based on the solvent system.

The solvent system can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the solvent system.

When the first resist is formed from a vinyl aromatic-based polymer, a particularly preferred organic-based solvent system includes one or more monoether solvents in a combined amount of from 70 to 98 wt % based on the solvent system, and one or more alcohol and/or ester solvents in a combined amount of from 2 to 30 wt % based on the solvent system. The solvent system is typically present in the overcoat composition in an amount of from 90 to 99 wt %, preferably from 95 to 99 wt %, based on the overcoat composition.

In embodiments in which the first resist is a negative tone development (NTD) resist, suitable organic solvents include, but are not limit to, n-butyl acetate, 2-heptanone, propylene glycol methyl ether, propylene glycol methyl ether acetate, and combinations thereof.

### Optional Additives

The overcoat composition may include additives having various purposes, depending on the particular chemistry being used. In some embodiments, a surfactant may be included in the overcoat composition. A surfactant may be included in the overcoat composition to help with coating quality, especially when needing to fill thin gaps between features of the first resist. Any suitable surfactant known in the art may be included in the overcoat composition.

### Second Resist Composition

In an embodiment of present disclosure, a second resist composition of a second resist layer 116 (see FIG. 1E) can be a composition that can include a third polymer, a solvent, and may also contain additional, optional components, including a crosslinker. In another embodiment, the second resist composition may further include an SSA. In some embodiments, the SSA may comprise materials such as described above, and the description is not repeated herein.

### Third Polymer

In an embodiment, the third polymer can be a polymer made from monomers including acrylates, methacrylates, norbornene, vinyl aromatic monomers such as styrene and p-hydroxystyrene, combinations thereof, or the like. Each monomer can include a curable group, a linker group, a cleavable group, and/or a polymerizable group.

Exemplary structures of monomers can include, without limitation, the following:

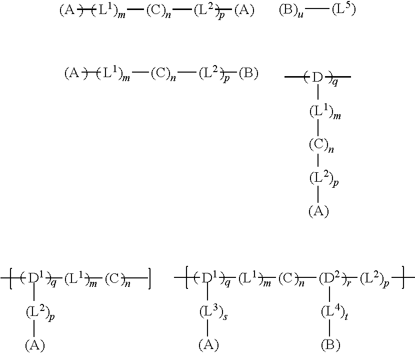

where A and B are curable groups, L¹-L⁵ are linker groups, C are cleavable groups, and D¹ and D² are polymerizable groups.

Example cleavable groups can include, without limitation, the following:

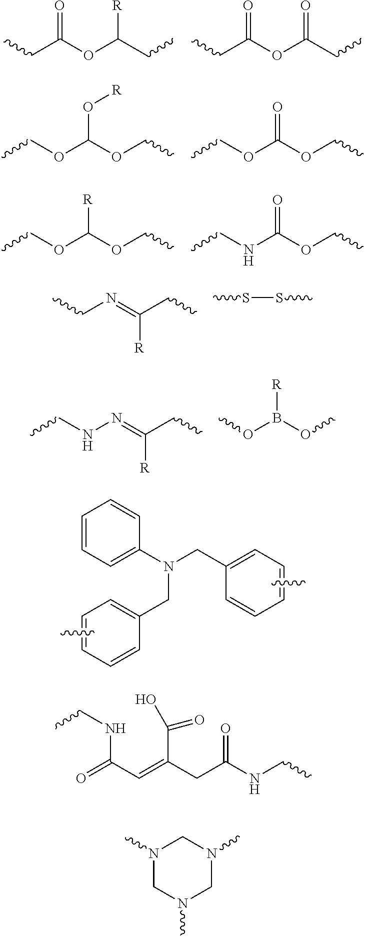

Crosslinking of polymers can be achieved by a variety of chemistries including the following non-limiting examples: vinyl ether+alcohol/carboxylic acid, glycouril+alcohol/carboxylic acid, benzocyclobutenes, oxiranes (epoxides), azides, azides+alkene/alkyne, acryloyl+free radical initiator, thiols, thiol+alkene, diazirines, diazo decomposition followed by carbene C—H insertion, or the like.

Example cross-linking chemistries can further include, without limitation, the following:

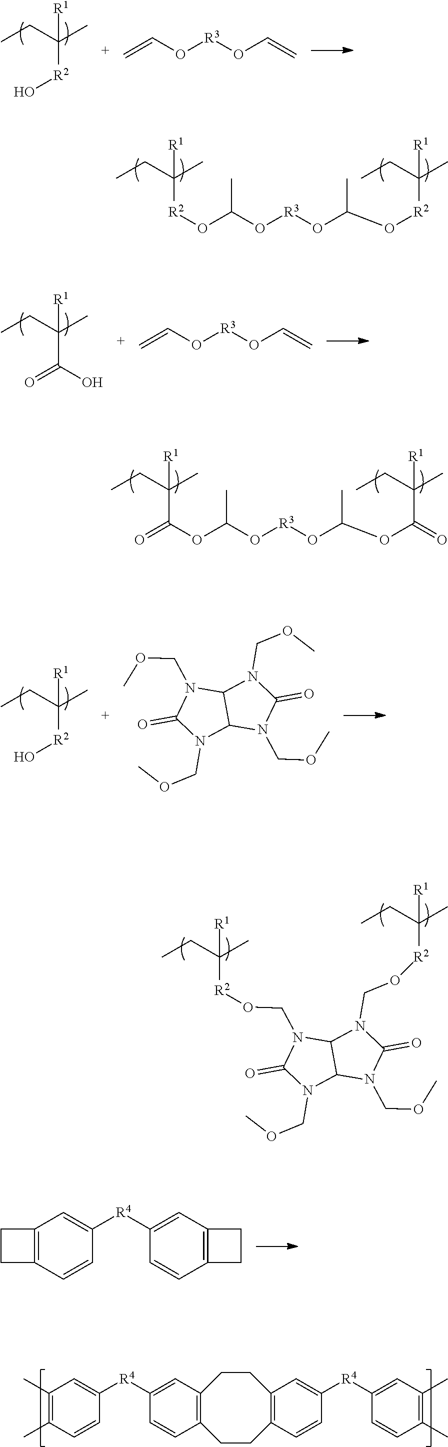

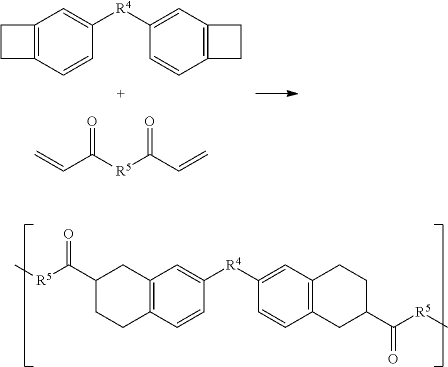

Example cleavable polyacrylate acrylates can include, without limitation, the following:

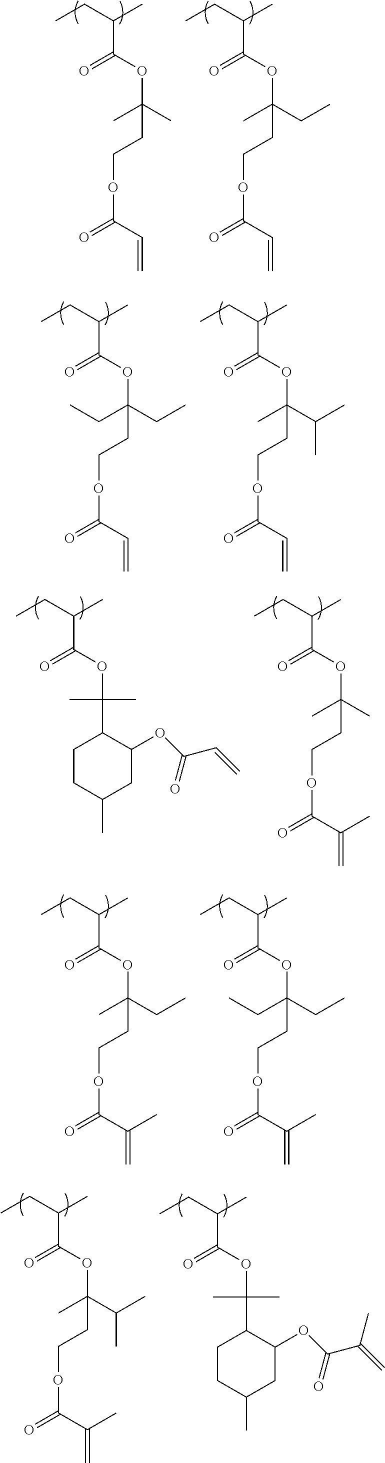

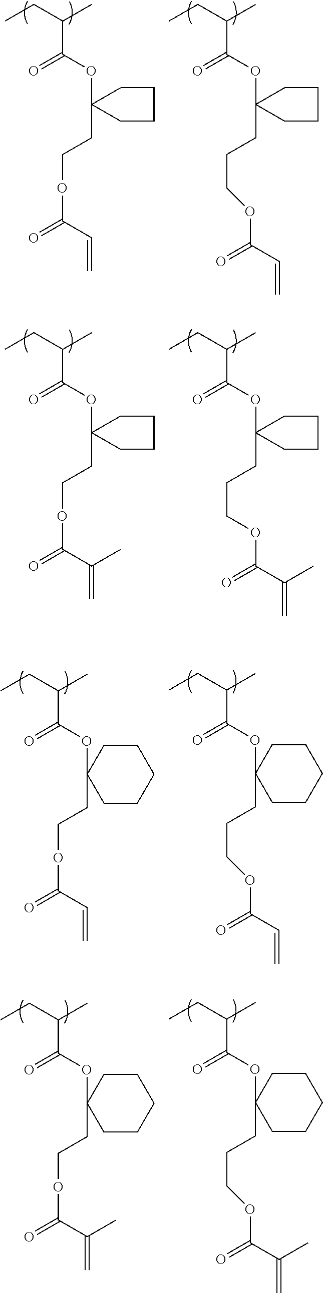

Example cleavable polyacrylate alcohols can include, without limitation, the following:

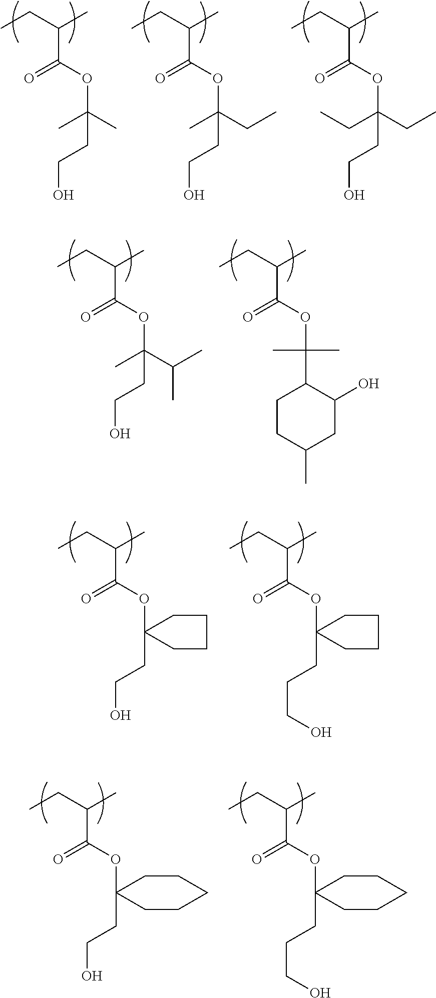

Example cleavable polyacrylate phthalates can include, without limitation, the following:

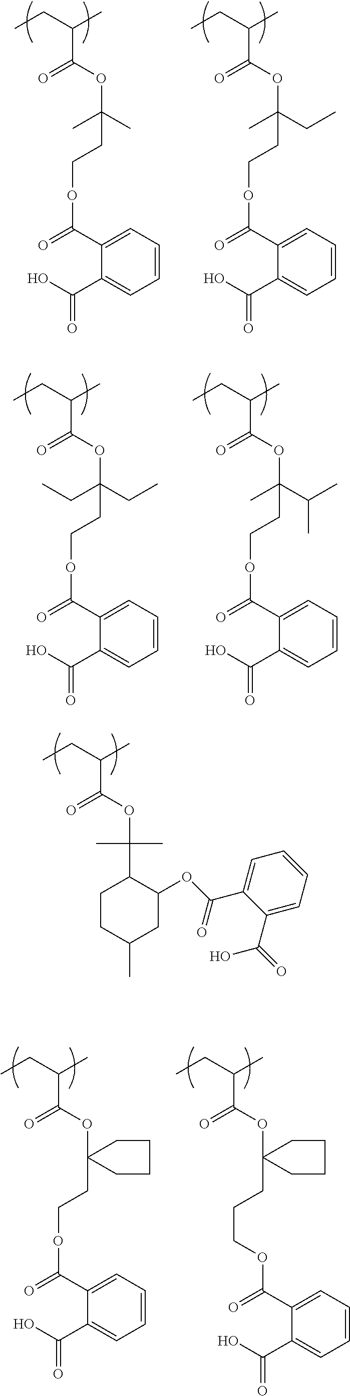

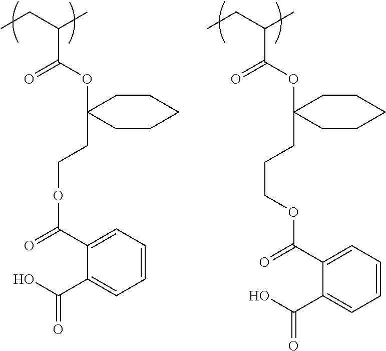

Example cleavable polymethacrylate acrylates can include, without limitation, the following:

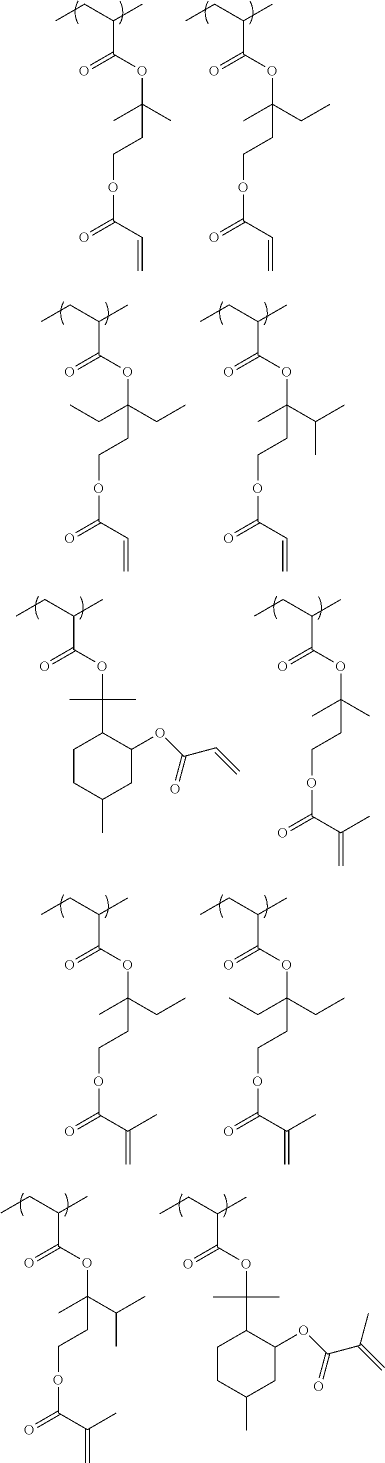

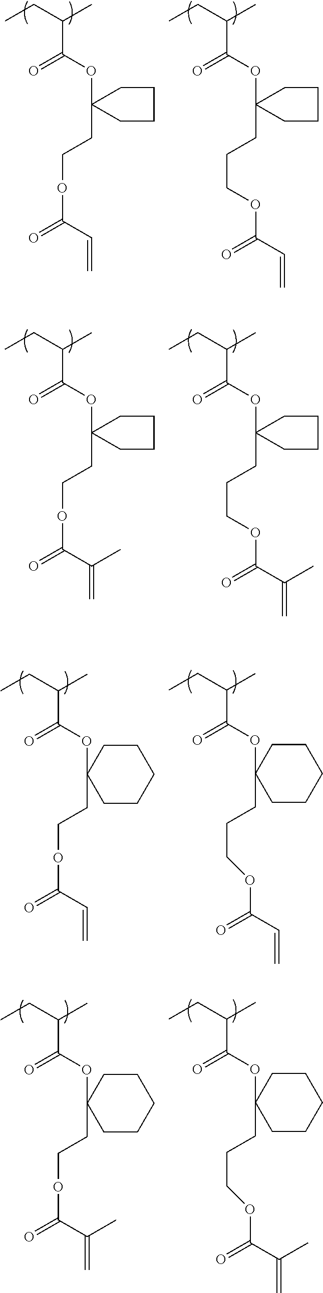

Example cleavable polymethacrylate alcohols can include, without limitation, the following:

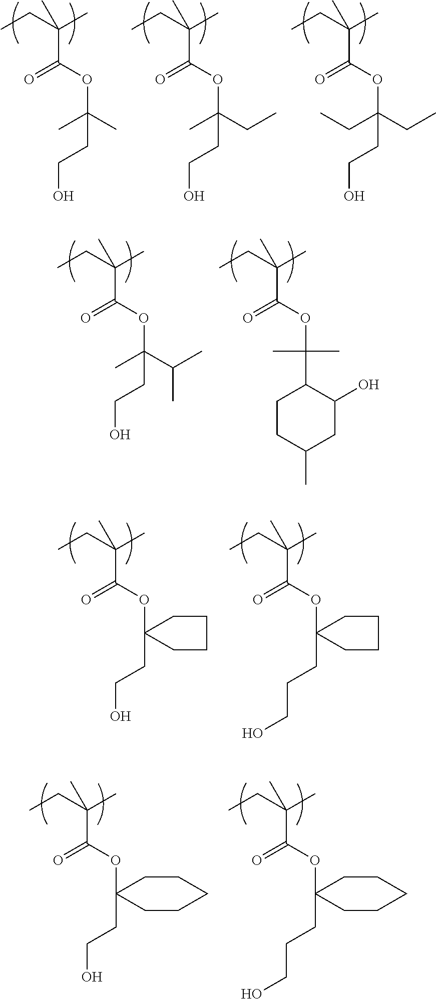

Example cleavable polystyrene alcohols can include, without limitation, the following:

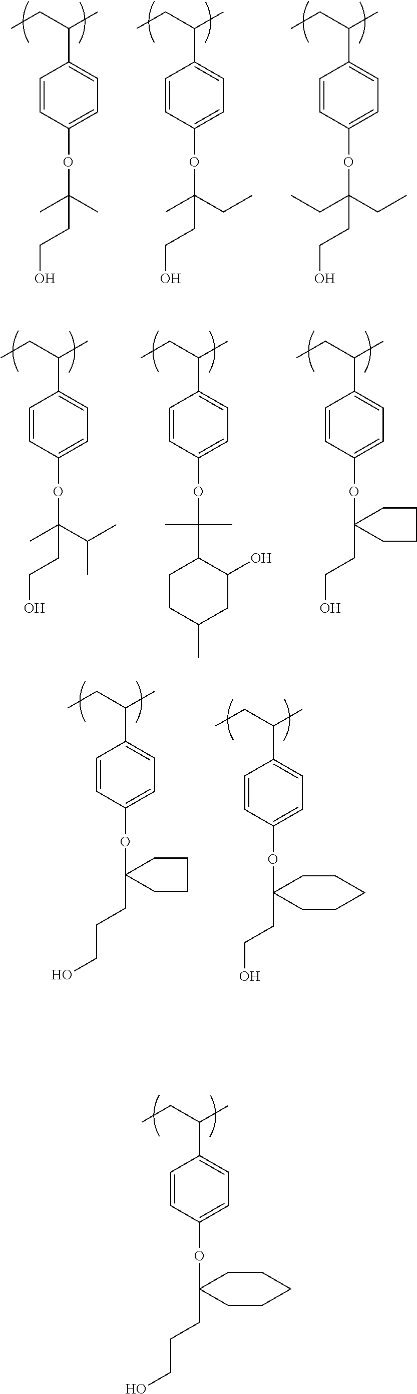

Example cleavable polystyrene phthalates can include, without limitation, the following:

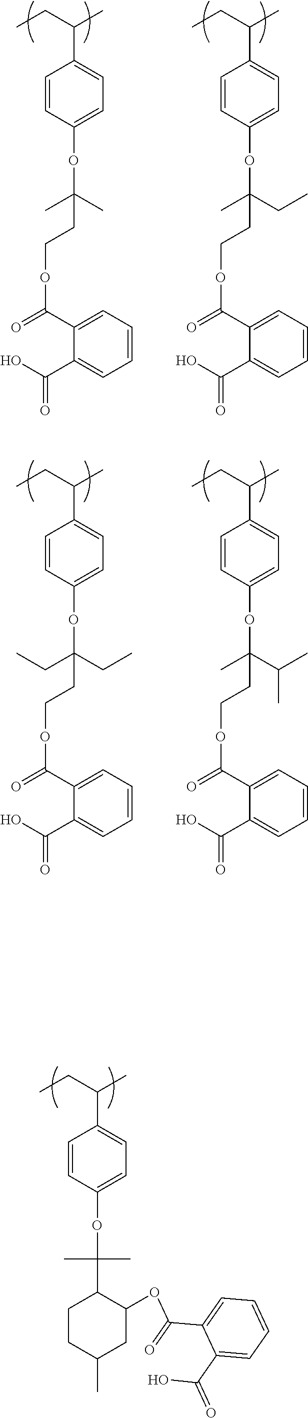

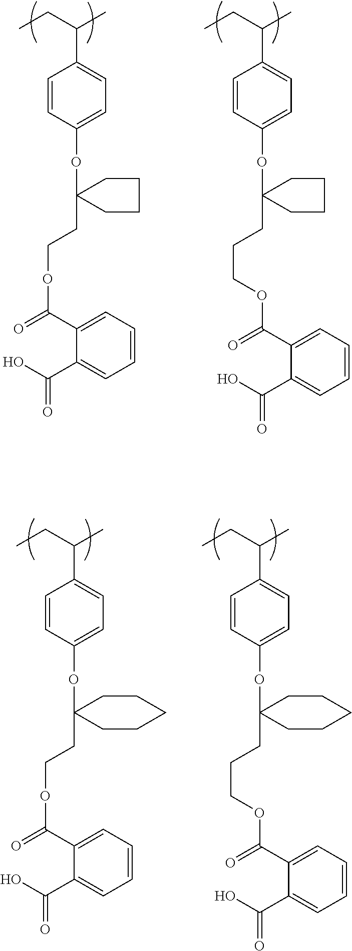

### Solvents

In an embodiment of present disclosure, the second resist composition of the second resist layer 116 (see FIG. 1E) can include a solvent. The solvent may be any suitable solvent that may facilitate dissolution of the components of the second resist composition, provided that it does not dissolve the first resist. Suitable solvents have been described previously.

### Crosslinkers

In an embodiment of present disclosure, the second resist composition of the second resist layer 116 (see FIG. 1E) can include an optional crosslinker. In some embodiments, the second resist composition can be crosslinked, e.g. by thermal and/or radiation treatment. The crosslinker component is generally a compound capable of reacting with the one or more functional groups capable of crosslinking. Examples, without limitation, of such crosslinking agents are resins containing melamines, methylols, glycoluril, polymeric glycolurils, benzoguanamine, urea, hydroxy alkyl amides, epoxy and epoxy amine resins, blocked isocyanates, and divinyl monomers. For example, suitable crosslinkers include amine-based crosslinkers such as melamine materials, including melamine resins such as manufactured by American Cyanamid and sold under the tradename of Cymel 300, 301, 303, 350, 370, 380, 1116 and 1130. Suitable glycourils include glycourils available from American Cyanamid. Suitable benzoquanamines and urea-based materials can include resins such as the benzoquanamine resins available from American Cyanamid under the name Cymel 1123 and 1125, and urea resins available from American Cyanamid under the names of Beetle 60, 65 and 80. Aromatic methylols, such as 2,6 bishydroxymethyl p-cresol, can also be used. In addition to being commercially available, such amine-based resins may be prepared, for example, by the reaction of acrylamide or methacrylamide copolymers with formaldehyde in an alcohol-containing solution, or alternatively by the copolymerization of N-alkoxymethyl acrylamide or methacrylamide with other suitable monomers.

In some embodiments, crosslinkers include methoxy-methylated glycoluril, butoxy-methylated glycoluril, methoxy-methylated melamine, butoxy-methylated melamine, methoxymethyl benzoguanamine, butoxymethyl benzoguanamine, methoxymethyl urea, butoxymethyl urea, methoxymethyl thiourea or butoxymethyl thiourea, combinations thereof, or the like. In addition, condensates of these compounds can also be used. Other suitable low basicity crosslinkers include hydroxy compounds, particularly polyfunctional compounds such as phenyl or other aromatics having one or more hydroxy or hydroxy alkyl substituents such as a C1-8 hydroxyalkyl substituents. Phenol compounds are generally preferred such as di-methanolphenol (C₆H₃(CH₂OH)₂OH) and other compounds having adjacent (within 1-2 ring atoms) hydroxy and hydroxyalkyl substitution, particularly phenyl or other aromatic compounds having one or more methanol or other hydroxylalkyl ring substituent and at least one hydroxy adjacent such hydroxyalkyl substituent. Preferred examples include substituted bi-phenol compounds, substituted tris-phenol compounds, methylolated phenol compounds, methylolated bisphenol compounds, substituted phenol novolaks, substituted cresol novolaks, combinations thereof, or the like.

In some embodiments, additional groups capable of reacting with the resin include, for example, epoxy group, oxetanyl group, oxazoline group, cyclocarbonate group, alkoxysilyl group, alkoxyalkyl group, aziridinyl group, methylol group, hydroxy group, isocyanate group, acetal group, hydroxysilyl group, ketal group, vinylether group, aminomethylol group, alkoxymethylamino group, imino group, combinations thereof, or the like.

Such compounds include, for example, compounds having an epoxy group such as triglycidyl-p-aminophenol, tetraglycidyl meta-xylene diamine, tetraglycidyl diamino diphenylmethane, tetraglycidyl-1,3-bisaminomethylcyclohexane, bisphenol-A-diglycidyl ether, bisphenol-S-diglycidyl ether, resorcinol diglycidyl ether, diglycidyl phthalate, neopentyl glycol diglycidyl ether, polypropylene glycol diglycidyl ether, cresol novolak polyglycidyl ether, tetrabromo bisphenol-A-diglycidyl ether, bisphenol hexafluoro acetone diglycidyl ether, glycerin triglycidyl ether, pentaerythritol diglycidyl ether, tris-(2,3-epoxypropyl) isocyanurate, monoallyldiglycidyl isocyanurate, glycidyl methacrylate, a combination thereof, or the like.

In addition, the compounds having a cyclocarbonate group includes, for example, a compound having a cyclocarbonate group obtained by the reaction of the compound having epoxy group with carbon dioxide, 1,2-propylene carbonate, phenyldioxolone, vinylethylene carbonate, butylene carbonate, tetrachloroethylene carbonate, chloroethylene glycol carbonate, 4-chloromethyl-1,3-dioxolan-2-one, 1,2-dichloroethylene carbonate, 4-(1-propenyloxymethyl)-1,3-dioxolan-2-one, glycerin carbonate, (chloromethyl)ethylene carbonate, 1-benzylglycelol-2,3-carbonate, 4,4-dimethyl-5-methylene-1,3-dioxolan-2-one, and 3,3,3-trifluoropropylene carbonate, or the like.

The compounds having an isocyanate group include, for example, p-phenylenediisocyanate, biphenyldiisocyanate, methylenebis(phenylisocyanate), 2-isocyanate ethyl methacrylate, 1,4-cyclohexyl diisocyanate, 1,3,5-tris(6-isocyanatehexyl)triazinetrione, 1-isocyanatenaphthalene, 1,5-naphthalene diisocyanate, 1-butylisocyanate, cyclohexylisocyanate, benzylisocyanate, 4-chlorophenylisocyanate, isocyanate trimethylsilane, and hexylisocyanate, combinations thereof, or the like.

The compounds having an alkoxysilyl group include, for example, triethoxyoctylsilane, tris[3-trimethoxysilyl) propyl]isocyanurate, 3-trimethoxysilyl)-N-[3 (trimethoxysilyl) propyl]-1-propanamine, 3-(trimethoxysilyl) propylmethacrylate, 3-isocyanate propyltriethoxysilane, 1,4-bis(trimethoxysilyl)benzene, phenyltriethoxysilane, methyltriethoxysilane, (3-trimethoxysilylpropyl) maleate, 3-(2-aminoethylamino) propyltrimethoxysilane, methyltriactoxyslane, trimethoxy-2-(3,4-epoxycyclohexyl)ethylsilane, 3-trimethoxysilylpropylmethacrylate, trimethoxypropylsilane, 4-(chloromethyl)phenyltrimethoxysilane, 2-(3,4-epoxycyclohexyl)ethyltriethoxysilane, triethoxy-n-dodecylsilane and 2-mercaptoethyl triethoxysilane, combinations thereof, or the like.

In some embodiments, additional compounds include melamine compounds, urea compounds, glycoluril compounds and benzoguanamine compounds that the hydrogen atom of the amino group is substituted by methylol group or alkoxymethyl group. Example compounds include hexamethoxymethyl melamine, tetramethoxymethyl benzoguanamine, 1,3,4,6-tetrakis(butoxymethyl)glycoluril, 1,3,4,6-tetrakis(hydroxymethyl)glycoluril, 1,3-bis(hydroxymethyl) urea, 1,1,3,3-tetrakis(butoxymethyl) urea, 1,1,3,3-tetrakis(methoxymethyl) urea, 1,3-bis(hydroxymethyl)-4,5-dihydroxy-2-imidazolinone, 1,3-bis(methoxymethyl)-4,5-dimethoxy-2-imidazolinone, methoxymethyl type melamine compounds manufactured by Mitsui Cytec Co., Ltd. (trade name: Cymel 300, Cymel 301, Cymel 303, Cymel 350), butoxymethyl type melamine compounds (trade name: Mycoat 506, Mycoat 508), glycoluril compounds (trade name: Cymel 1170, Powderlink 1174), methylated urea resins (trade name: UFR 65), butylated urea resins (trade name: UFR300, U-VAN 10S60, U-VAN 10R, U-VAN 11HV), urea/formaldehyde resins manufactured by Dainippon Ink and Chemistry Incorporated (high condensation type, trade name: Beckamine J-300S, Beckamine P-955, Beckamine N), combinations thereof, or the like. The compounds obtained by condensing the melamine compounds, urea compounds, glycoluril compounds and benzoguanamine compounds that the hydrogen atom of the amino group is substituted by methylol group or alkoxymethyl group, may be also used. For example, the compound includes a compound with a high molecular weight that is produced from a melamine compound (Cymel 303) and a benzoguanamine compound (trade name: Cymel 1123) that is disclosed in U.S. Pat. No. 6,323,310.

In some embodiments, additional crosslinkers are vinyl ether crosslinkers. It is preferred that the vinyl ether crosslinkers be multi-functional, and more preferably tri- and tetra-functional. Suitable vinyl ether crosslinkers include those selected from the group consisting of ethylene glycol vinyl ether, trimethylolpropane trivinyl ether, 1,4-cyclohexane dimethanol divinyl ether, {2-[(2,4,5-tris {[2-(vinyloxy) ethoxy]methyl}phenyl) methoxy]ethoxy}ethene, tri[2-(vinyloxy)ethyl]1,3,5-benzenetricarboxylate, and mixtures thereof.

In some embodiments, a crosslinker component of the second resist composition is present in an amount of between 5 and 50 weight percent of total solids (all components except solvent carrier) of the second resist composition. In an embodiment, a crosslinker component of the second resist composition is present in an amount of between 7 and 25 weight percent of total solids.

### Developers

In an embodiment of the present disclosure, a developer that contains an organic solvent can include an organic solvent conventionally used in the manufacture of electronic devices. In an embodiment of the present disclosure, a developer that contains an organic solvent can include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol and 4-methyl-2-pentanol; propylene glycol monomethyl ether (PGME), ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; and combinations thereof, for example. Of these, some preferred organic solvents can be PGME, PGMEA, EL, GBL, HBM, CHO, or combinations thereof, for example.

The exposed resist layer may be developed with either a positive tone development (PTD) or negative tone development (NTD) process. In an embodiment, suitable developers for a PTD process can include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like, for example.

Conversely, in an embodiment, suitable developers for an NTD process can be organic solvent-based, which can mean the cumulative content of organic solvents in the developer is 50 wt % or more, typically 95 wt % or more, 98 wt % or more, or 100 wt %, based on total weight of the developer. For an embodiment, suitable organic solvents for the PTD developer can include, for example, those chosen from ketones, esters, ethers, hydrocarbons, and mixtures thereof. In an embodiment, a developer can be typically 2-heptanone or n-butyl acetate.

Example embodiments of the disclosure are described below. Other embodiments can also be understood from the entirety of the specification as well as the claims filed herein.

Example 1. A method including forming mandrels over a substrate. The mandrels include a first material having a first solubility-shifting mechanism. The method further including absorbing a solubility-shifting agent into the mandrels to form absorbed regions in the mandrels and depositing a resist layer over the mandrels and the substrate. The resist layer includes a second material having a second solubility-shifting mechanism different from the first solubility-shifting mechanism. The method further including diffusing a catalyst of/from the solubility-shifting agent into the resist layer to form solubility-shifted regions in the resist layer, and selectively removing the solubility-shifted regions of the resist layer. Remaining regions of the resist layer and the mandrels form a patterned mask over the substrate.

Example 2. The method of example 1, further including, before diffusing the catalyst of/from the solubility-shifting agent into the resist layer, curing the resist layer.

Example 3. The method of one of examples 1 and 2, where the first material includes a first polymer including acid-labile groups.

Example 4. The method of one of examples 1 to 3, where the second material includes curable groups and cleavable groups.

Example 5. The method of one of examples 1 to 4, where the second material includes a degradable thermoset.

Example 6. The method of one of examples 1 to 5, where the second material includes polyacrylate phthalates, polystyrene phthalates, polystyrene alcohols, polymethacrylate alcohols, polyacrylate alcohols, polymethacrylate acrylates, or polyacrylate acrylates.

Example 7. The method of one of examples 1 to 6, where the solubility-shifted regions are selectively removed using an organic solvent.

Example 8. A method including forming a first patterned resist layer over a substrate. The first patterned resist layer includes a first material including acid-labile groups. The method further including absorbing a solubility-shifting agent into the first patterned resist layer to form absorbed regions in the first patterned resist layer and depositing a second resist layer over the first patterned resist layer and the substrate. The second resist layer includes a second material including curable groups and cleavable groups. The method further including generating a catalyst from the solubility-shifting agent, diffusing the catalyst into the second resist layer to form deprotected regions in the second resist layer, and selectively removing the deprotected regions of the second resist layer. Remaining regions of the second resist layer and the first patterned resist layer form a patterned mask over the substrate.

Example 9. The method of example 8, further including, before generating the catalyst from the solubility-shifting agent, curing the second resist layer.

Example 10. The method of one of examples 8 and 9, where the second material includes a degradable thermoset.

Example 11. The method of one of examples 8 to 10, where the second material includes polyacrylate phthalates, polystyrene phthalates, polystyrene alcohols, polymethacrylate alcohols, polyacrylate alcohols, polymethacrylate acrylates, or polyacrylate acrylates.

Example 12. The method of one of examples 8 to 11, where the deprotected regions are selectively removed using an organic solvent.

Example 13. The method of one of examples 8 to 12, where the diffused catalyst cleaves cleavable bonds of the second material.

Example 14. The method of one of examples 8 to 13, where the second material further includes linker groups and polymerizable groups.

Example 15. A method including forming a first patterned resist layer over a substrate. The first patterned resist layer includes a first material comprising acid-labile groups. The method further including depositing an overcoat over the first patterned resist layer and the substrate. The overcoat includes a solubility-shifting agent. The method further including absorbing the solubility-shifting agent into the first patterned resist layer to form absorbed regions in the first patterned resist layer, selectively removing the overcoat, and depositing a second resist layer over the first patterned resist layer and the substrate. The second resist layer includes a degradable thermoset. The method further including generating a catalyst from the solubility-shifting agent, diffusing the catalyst into the second resist layer to form deprotected regions in the second resist layer, and selectively removing the deprotected regions of the second resist layer. Remaining regions of the second resist layer and the first patterned resist layer form a patterned mask over the substrate.

Example 16. The method of example 15, where the degradable thermoset includes curable groups and cleavable groups.

Example 17. The method of one of examples 15 and 16, where the diffused catalyst cleaves cleavable bonds of the cleavable groups.

Example 18. The method of one of examples 15 to 17, where the degradable thermoset further includes linker groups and polymerizable groups.

Example 19. The method of one of examples 15 to 18, where the overcoat is selectively removed using an organic solvent.

Example 20. The method of one of examples 15 to 19, where generating and diffusing the catalyst includes performing a baking process.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming mandrels over a substrate, wherein the mandrels comprise a first material having a first solubility-shifting mechanism;
absorbing a solubility-shifting agent into the mandrels to form absorbed regions in the mandrels;
depositing a resist layer over the mandrels and the substrate, wherein the resist layer comprises a second material having a second solubility-shifting mechanism different from the first solubility-shifting mechanism;
diffusing a catalyst of/from the solubility-shifting agent into the resist layer to form solubility-shifted regions in the resist layer; and
selectively removing the solubility-shifted regions of the resist layer, wherein remaining regions of the resist layer and the mandrels form a patterned mask over the substrate.

2. The method of claim 1, further comprising, before diffusing the catalyst of/from the solubility-shifting agent into the resist layer, curing the resist layer.

3. The method of claim 1, wherein the first material comprises a first polymer comprising acid-labile groups.

4. The method of claim 1, wherein the second material comprises curable groups and cleavable groups.

5. The method of claim 1, wherein the second material comprises a degradable thermoset.

6. The method of claim 1, wherein the second material comprises polyacrylate phthalates, polystyrene phthalates, polystyrene alcohols, polymethacrylate alcohols, polyacrylate alcohols, polymethacrylate acrylates, or polyacrylate acrylates.

7. The method of claim 1, wherein the solubility-shifted regions are selectively removed using an organic solvent.

8. A method comprising:
forming a first patterned resist layer over a substrate, wherein the first patterned resist layer comprises a first material comprising acid-labile groups;
absorbing a solubility-shifting agent into the first patterned resist layer to form absorbed regions in the first patterned resist layer;
depositing a second resist layer over the first patterned resist layer and the substrate, wherein the second resist layer comprises a second material comprising curable groups and cleavable groups;
generating a catalyst from the solubility-shifting agent;
diffusing the catalyst into the second resist layer to form deprotected regions in the second resist layer; and
selectively removing the deprotected regions of the second resist layer, wherein remaining regions of the second resist layer and the first patterned resist layer form a patterned mask over the substrate.

9. The method of claim 8, further comprising, before generating the catalyst from the solubility-shifting agent, curing the second resist layer.

10. The method of claim 8, wherein the second material comprises a degradable thermoset.

11. The method of claim 8, wherein the second material comprises polyacrylate phthalates, polystyrene phthalates, polystyrene alcohols, polymethacrylate alcohols, polyacrylate alcohols, polymethacrylate acrylates, or polyacrylate acrylates.

12. The method of claim 8, wherein the deprotected regions are selectively removed using an organic solvent.

13. The method of claim 8, wherein the diffused catalyst cleaves cleavable bonds of the second material.

14. The method of claim 8, wherein the second material further comprises linker groups and polymerizable groups.

15. A method comprising:
forming a first patterned resist layer over a substrate, wherein the first patterned resist layer comprises a first material comprising acid-labile groups;
depositing an overcoat over the first patterned resist layer and the substrate, wherein the overcoat comprises a solubility-shifting agent;
absorbing the solubility-shifting agent into the first patterned resist layer to form absorbed regions in the first patterned resist layer;
selectively removing the overcoat;
depositing a second resist layer over the first patterned resist layer and the substrate, wherein the second resist layer comprises a degradable thermoset;
generating a catalyst from the solubility-shifting agent;
diffusing the catalyst into the second resist layer to form deprotected regions in the second resist layer; and
selectively removing the deprotected regions of the second resist layer, wherein remaining regions of the second resist layer and the first patterned resist layer form a patterned mask over the substrate.

16. The method of claim 15, wherein the degradable thermoset comprises curable groups and cleavable groups.

17. The method of claim 16, wherein the diffused catalyst cleaves cleavable bonds of the cleavable groups.

18. The method of claim 15, wherein the degradable thermoset further comprises linker groups and polymerizable groups.

19. The method of claim 15, wherein the overcoat is selectively removed using an organic solvent.

20. The method of claim 15, wherein generating and diffusing the catalyst comprises performing a baking process.
